(19) United States
(12) Patent Application Publication
(10) Pub. No.: US 2025/0340780 A1
(43) Pub. Date: Nov. 6, 2025

(54) LIQUID CRYSTAL COMPOSITION, LIQUID CRYSTAL CURED LAYER, OPTICAL FILM, POLARIZING PLATE, IMAGE DISPLAY APPARATUS, AND COPOLYMER

(71) Applicant: FUJIFILM Corporation, Tokyo (JP)

(72) Inventors: Tomonori MIMURA, Kanagawa (JP); Akio TAMURA, Kanagawa (JP)

(73) Assignee: FUJIFILM Corporation, Tokyo (JP)

(21) Appl. No.: 19/271,174

(22) Filed: Jul. 16, 2025

Related U.S. Application Data
(63) Continuation of application No. PCT/JP2024/004911, filed on Feb. 14, 2024.

(30) Foreign Application Priority Data
Feb. 24, 2023 (JP) 2023-027263
Apr. 18, 2023 (JP) 2023-067928

(51) Int. Cl. C09K 19/38; C08F 222/10; C08F 230/08; C09K 19/60

(52) U.S. Cl. CPC C09K 19/3852; C08F 222/102; C08F 230/085; C09K 19/601

(57) ABSTRACT

A liquid crystal composition which contains a copolymer having excellent compatibility with a liquid crystal compound, and has excellent leveling properties and excellent adhesiveness, as well as a liquid crystal cured layer, an optical film, a polarizing plate, an image display apparatus, and a copolymer. The liquid crystal composition includes a copolymer containing a repeating unit A and a repeating unit B, and a liquid crystal compound, in which the repeating unit A is a repeating unit represented by Formula (A1) or a repeating unit represented by Formula (A2), and the repeating unit B is a repeating unit having at least one group selected from the group consisting of a hydroxy group, a boronic acid group, a boronic acid ester group, a boronic acid amide group, an epoxy group, an oxetane group, a vinyl group, a styryl group, a (meth)acryloyl group, and a maleimide group.

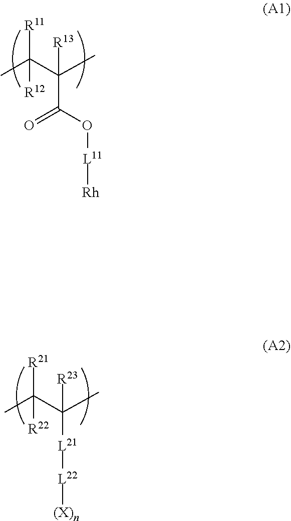

### CROSS-REFERENCE TO RELATED APPLICATIONS

This application is a Continuation of PCT International Application No. PCT/JP2024/004911 filed on Feb. 14, 2024, which was published under PCT Article 21 (2) in Japanese, and which claims priority under 35 U.S.C. § 119(a) to Japanese Patent Application No. 2023-027263 filed on Feb. 24, 2023 and Japanese Patent Application No. 2023-067928 filed on Apr. 18, 2023. The above applications are hereby expressly incorporated by reference, in their entirety, into the present application.

### BACKGROUND OF THE INVENTION

### 1. Field of the Invention

The present invention relates to a liquid crystal composition, a liquid crystal cured layer, an optical film, a polarizing plate, an image display apparatus, and a copolymer.

### 2. Description of the Related Art

Optical films such as an optical compensation sheet and a phase difference film are used in various image display apparatuses from the viewpoint of elimination of image coloration, viewing angle expansion, and the like.

A stretched birefringence film has been used as an optical film. However, in recent years, it has been suggested to use a liquid crystal cured layer formed of a liquid crystal compound in place of the stretched birefringence film.

For example, JP2016-095421A describes “a retardation film consisting of a cured product of a composition for forming a retardation layer, which contains a liquid crystal compound, a surfactant, and a solvent, in which the surfactant is a polyether-modified silicone having a repeating unit represented by General Formula (I)” as a component contained in a liquid crystal composition for forming a liquid crystal cured layer (claim 1).

### SUMMARY OF THE INVENTION

As a result of studying a liquid crystal composition containing a copolymer and a liquid crystal compound described in JP2016-095421A and the like, the present inventors have found that depending on the structure of the copolymer, it is difficult to achieve a balance between the leveling properties of the liquid crystal composition, the compatibility between the copolymer and the liquid crystal compound, and the adhesiveness of a film formed using the liquid crystal composition to a member adjacent to the film in a case where the film is adhered to an adherend, and there is room for improvement.

Hereinafter, the fact that the adhesiveness of the film formed using the liquid crystal composition to a member adjacent to the film in a case where the film is adhered to the adherend is excellent is also simply referred to as “excellent adhesiveness”.

Therefore, an object of the present invention is to provide a liquid crystal composition which contains a copolymer having excellent compatibility with a liquid crystal compound, and has excellent leveling properties and excellent adhesiveness.

In addition, another object of the present invention is to provide a liquid crystal cured layer, an optical film, a polarizing plate, an image display apparatus, and a copolymer.

The present inventors have found that the objects can be accomplished by the following configurations.

### 1

A liquid crystal composition comprising a copolymer containing a repeating unit A and a repeating unit B; and a liquid crystal compound, in which the repeating unit A is a repeating unit represented by Formula (A1) or a repeating unit represented by Formula (A2), and the repeating unit B is a repeating unit having at least one group selected from the group consisting of a hydroxy group, a boronic acid group, a boronic acid ester group, a boronic acid amide group, an epoxy group, an oxetane group, a vinyl group, a styryl group, a (meth)acryloyl group, and a maleimide group.

### 2

The liquid crystal composition according to [1], in which the repeating unit B is a repeating unit represented by Formula (B1).

### 3

The liquid crystal composition according to [1] or [2], in which the repeating unit A is a repeating unit represented by Formula (a1).

### 4

The liquid crystal composition according to any one of [1] to [3], in which a weight-average molecular weight of the copolymer is 8,000 or more and less than 80,000.

### 5

The liquid crystal composition according to [1], in which the repeating unit B has at least two groups selected from the group consisting of a hydroxy group, a boronic acid group, a boronic acid ester group, an epoxy group, an oxetane group, a vinyl group, and a (meth)acryloyl group.

### 6

The liquid crystal composition according to any one of [1] to [5], in which a content of the repeating unit A is 40 to 70 mol % with respect to all repeating units of the copolymer.

### 7

The liquid crystal composition according to any one of [1] to [6], in which the liquid crystal compound is a polymerizable liquid crystal compound.

### 8

The liquid crystal composition according to [7], in which the polymerizable liquid crystal compound is at least one polymerizable liquid crystal compound selected from the group consisting of a polymerizable rod-like liquid crystal compound and a polymerizable disk-like liquid crystal compound.

### 9

The liquid crystal composition according to any one of [1] to [8], further comprising a dichroic substance.

### 10

A liquid crystal cured layer obtained by immobilizing an alignment state of the liquid crystal compound in the liquid crystal composition according to any one of [1] to [9].

### 11

An optical film comprising the liquid crystal cured layer according to [10].

### 12

A polarizing plate comprising the optical film according to and a polarizer.

### 13

An image display apparatus comprising the optical film according to or the polarizing plate according to [12].

### 14

A copolymer comprising a repeating unit A and a repeating unit B, in which the repeating unit A is a repeating unit represented by Formula (A1) or a repeating unit represented by Formula (A2), and the repeating unit B is a repeating unit having at least one group selected from the group consisting of a boronic acid group, a boronic acid ester group, an epoxy group, an oxetane group, and a (meth)acryloyl group.

According to the present invention, it is possible to provide a liquid crystal composition which contains a copolymer having excellent compatibility with a liquid crystal compound, and has excellent leveling properties and excellent adhesiveness.

In addition, the present invention can also provide a liquid crystal cured layer, an optical film, a polarizing plate, an image display apparatus, and a copolymer.

### BRIEF DESCRIPTION OF THE DRAWINGS

FIG. 1 is a schematic cross-sectional view showing an example of the optical film.

### DESCRIPTION OF THE PREFERRED EMBODIMENTS

Hereinafter, the present invention will be described in detail.

Although the configuration requirements to be described below may be described based on representative embodiments of the present invention, the present invention is not limited to such embodiments.

In the present specification, any numerical range expressed by using “to” means a range including the numerical values before and after the “to” as a lower limit value and an upper limit value, respectively.

In the present specification, for various components, one type of substance corresponding to various components may be used alone, or two or more types thereof may be used in combination. Here, in a case where two or more types of substances are used in combination for various components, the content of the component means the total content of the substances used in combination unless otherwise specified.

In addition, in the present specification, a bonding direction of a divalent group (for example, —O—CO—) described is not particularly limited, and for example, in a case where L² in an “L¹-L²-L³” bond is —O—CO—, and a bonding position on the L¹ side is represented by *1 and a bonding position on the L³ side is represented by *2, L² may be *1—O—CO—*2 or *1—CO—O—*2.

The compounds described in the present specification may include isomers unless otherwise specified. The isomers may be any of structural isomers, geometric isomers, or optical isomers that each compound can have. In addition, in a case where only a specific isomer of a compound is shown, it indicates that the specific isomer is preferable among isomers that the compound can take.

In the present specification, (meth)acrylic acid includes the concepts of both acrylic acid and methacrylic acid. In addition, the (meth)acryloyl group includes the concepts of both an acryloyl group and a methacryloyl group.

“Solid content” of a liquid crystal composition means a component forming a layer (for example, a liquid crystal cured layer) formed of the liquid crystal composition, and in a case where the composition contains a solvent (for example, organic solvent, water, and the like), the solid content means all components excluding the solvent. In addition, a liquid component is also regarded as the solid content in a case where the component is a component which forms the layer.

In the present specification, Re(λ) and Rth(λ) represent an in-plane retardation and a thickness-direction retardation at a wavelength λ, respectively. It is noted that unless otherwise specified, the wavelength λ refers to 550 nm.

In addition, in this specification, Re(λ) and Rth(λ) are values measured at a wavelength λ using AxoScan OPMF-1 (manufactured by Opto Science. Inc.).

Specifically, by inputting an average refractive index ((nx+ny+nz)/3) and a film thickness (d (μm)) in AxoScan OPMF-1, the following are calculated. Slow Axis Direction (°)

$$\begin{matrix}R e ( λ ) = R 0 ( λ ) \\ Rth ( λ ) = ( ( n x + ny ) / 2 - nz ) \times d\end{matrix}$$

It is noted that although R0(λ) is displayed as a numerical value calculated by AxoScan OPMF-1, R0(λ) means Re(λ).

### Liquid Crystal Composition

The liquid crystal composition according to the embodiment of the present invention is a liquid crystal composition containing a copolymer (hereinafter, also referred to as a “specific copolymer”) having a repeating unit A and a repeating unit B, and a liquid crystal compound.

In addition, the repeating unit A is a repeating unit represented by Formula (A1) or a repeating unit represented by Formula (A2), and the repeating unit B is a repeating unit having at least one group (hereinafter, also referred to as a “specific group B”) selected from the group consisting of a hydroxy group, a boronic acid group, a boronic acid ester group, a boronic acid amide group, an epoxy group, an oxetane group, a vinyl group, a styryl group, a (meth)acryloyl group, and a maleimide group.

In the present invention, as described above, by containing the specific copolymer having excellent compatibility with the liquid crystal compound, it is possible to provide a liquid crystal composition having both excellent leveling properties and excellent adhesiveness.

The details of the reason for this are not clear, but the present inventors presumed the reason to be as follows.

It is presumed that the specific copolymer includes the repeating unit A and the repeating unit B, and thus, in the liquid crystal composition, both leveling properties and adhesiveness are excellent because of structural features of the repeating units, and compatibility with the liquid crystal compound is also excellent.

Hereinafter, various components that can be contained in the liquid crystal composition according to the embodiment of the present invention will be described in detail.

### Specific Copolymer

The liquid crystal composition contains a specific copolymer.

The specific copolymer is a copolymer containing the repeating unit A and the repeating unit B.

### <Repeating Unit A>

The repeating unit A is a repeating unit represented by Formula (A1) or a repeating unit represented by Formula (A2).

The repeating unit A is preferably a repeating unit represented by Formula (A1), and Rh in Formula (A1) is a substituent (hereinafter, also referred to as a “substituent SI”) having two or more groups represented by Formula (S) and not having a fluorine atom.

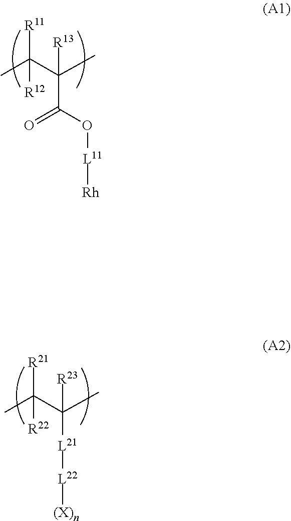

In Formula (A1),
R¹¹ and R¹² each independently represent a hydrogen atom or an alkyl group,
R¹³ represents a hydrogen atom or a substituent,
L¹¹ represents a single bond or a divalent linking group, and
Rh represents a substituent (substituent SI) having two or more groups represented by Formula (S) and not having a fluorine atom, or a hydrocarbon group having 10 or more carbon atoms (hereinafter, also referred to as a “substituent LQ”), which has two or more terminal methyl groups.

In Formula (A2),
R²¹ and R²² each independently represent a hydrogen atom or an alkyl group,
R²³ represents a hydrogen atom or a substituent,
L²¹ represents a single bond or a divalent linking group,
L²² represents an (n+1)-valent linking group having a heteroatom,
X represents an alkyl group having 5 to 40 carbon atoms (hereinafter, also referred to as a “substituent LR”), which has two or more terminal methyl groups, and
n represents an integer of 2 or more,
provided that a plurality of X's may be the same as or different from each other.

In Formula (A1), R¹¹ and R¹² each independently represent a hydrogen atom or an alkyl group.

Examples of the alkyl group represented by one aspect of R¹¹ and R¹² include a linear alkyl group having 1 to 18 carbon atoms, a branched alkyl group having 3 to 18 carbon atoms, and a cyclic alkyl group. Specific examples thereof include a methyl group, an ethyl group, a propyl group, an isopropyl group, a butyl group (for example, an n-butyl group, a sec-butyl group, an iso-butyl group, and a tert-butyl group), and a cyclohexyl group.

R¹¹ and R¹² are each preferably a hydrogen atom.

In Formula (A1), R¹³ represents a hydrogen atom or a substituent.

Examples of the substituent represented by one aspect of R¹³ include a hydroxy group, an alkyl group, an alkenyl group, and an aryl group.

In addition, examples of the substituent represented by one aspect of R¹³ also include a -L^{R}-hydroxy group, a -L^{R}-alkyl group, a -L^{R}-alkenyl group, and a -L^{R}-aryl group. LR represents a divalent linking group. Examples of the divalent linking group represented by one aspect of L^{R} include —O—, —S —, —C(═O)—, —NRN—, —CH═CH—, —C═C—, a divalent cyclic group, an alkylene group, and a divalent group obtained by combining these groups, and a-CH2-COO-alkylene group-hydroxy group is preferable. RN represents a hydrogen atom or an alkyl group having 1 to 12 carbon atoms.

As the alkyl group represented by one aspect of R^{13,} a linear alkyl group having 1 to 4 carbon atoms is preferable, and a methyl group or an ethyl group is more preferable.

It is preferable that R¹³ represents a hydrogen atom or a methyl group.

In Formula (A1), L¹¹ represents a single bond or a divalent linking group.

Examples of the divalent linking group represented by one aspect of L¹¹ include a divalent hydrocarbon group having 1 to 20 carbon atoms, and an alkylene group having 1 to 20 carbon atoms is preferable, and a linear alkylene group having 1 to 18 carbon atoms, a branched alkylene group having 3 to 18 carbon atoms, or cyclic alkylene group having 3 to 20 carbon atoms is more preferable.

L¹¹ is preferably a single bond or a linear alkylene group having 1 to 18 carbon atoms, and more preferably a single bond, a methylene group, an ethylene group, or a propylene group.

In Formula (A1), Rh represents a substituent SI or a substituent LQ.

From the viewpoint of further improving the leveling properties of the liquid crystal composition, the Rh is preferably the substituent SI.

The substituent SI represented by one aspect of Rh is not particularly limited as long as it is a substituent having two or more groups represented by Formula (S) and not having a fluorine atom.

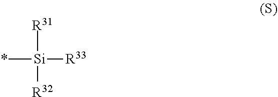

In Formula (S),

* represents a bonding position, and

R³¹, R³², and R³³ each independently represent an alkyl group, an alkenyl group, an aryl group, or an alkylenearyl group, provided that in the substituent (substituent SI) having two or more groups represented by Formula (S) and not having a fluorine atom, a plurality of R³¹'s may be the same as or different from each other, a plurality of R³²'s may be the same as or different from each other, and a plurality of R³³'s may be the same as or different from each other.

Examples of the alkyl group represented by one aspect of R³¹, R³², and R³³ include a linear alkyl group having 1 to 18 carbon atoms, a branched alkyl group having 3 to 18 carbon atoms, and a cyclic alkyl group.

Examples of the alkenyl group represented by one aspect of R³¹, R³², and R³³ include an alkenyl group having 2 to 12 carbon atoms.

Examples of the aryl group represented by one aspect of R³¹, R³², and R³³ include an aryl group having 6 to 12 carbon atoms. Specific examples thereof include a phenyl group, an α-methylphenyl group, and a naphthyl group.

Examples of the alkylene aryl group represented by one aspect of R³¹, R³², and R³³ include an alkylene aryl group having 7 to 30 carbon atoms.

From the viewpoint of reducing the surface tension of the liquid crystal composition and suppressing unevenness during formation of the liquid crystal cured layer, R³¹, R³², and R³³ in Formula (S) are preferably an alkyl group, and more preferably a linear alkyl group having 1 to 18 carbon atoms.

The number of groups represented by Formula (S) contained in the substituent SI is 2 or more, and from the viewpoint of reducing the surface tension of the liquid crystal composition and suppressing unevenness during formation of the liquid crystal cured layer, it is preferably 2 to 8, more preferably 3 to 6, and still more preferably 3 to 5.

As the substituent SI, a group represented by Formula (S1) is preferable, and a group represented by Formula (S2) is more preferable.

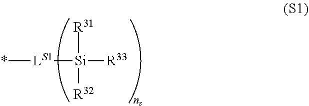

In Formula (S1),
* represents a bonding position.
R³¹, R³², and R³³ each independently represent an alkyl group, an alkenyl group, an aryl group, or an alkylenearyl group, provided that a plurality of R³¹'s may be the same as or different from each other, a plurality of R³²'s may be the same as or different from each other, and a plurality of R³³'s may be the same as or different from each other,
L^{S1} represents an (nₛ+1)-valent linking group not having a fluorine atom, and
nₛ represents an integer of 2 or more.

R³¹, R³², and R³³ in Formula (S1) have the same meanings as R³¹, R³², and R³³ in Formula (S), respectively, and suitable aspects thereof are also the same.

In Formula (S1), L^{S1} represents an (nₛ+1)-valent linking group not having a fluorine atom.

The (nₛ+1)-valent linking group not having a fluorine atom, represented by L^{S1}, is preferably, for example, an nₛ+1-valent hydrocarbon group having 1 to 15 carbon atoms, which may have a substituent other than a fluorine atom, and in which a part of carbon atoms constituting the hydrocarbon group may be substituted with a heteroatom. For example, in a case where the (nₛ+1)-valent linking group is a trivalent hydrocarbon group, one —CH₂— or two or more non-adjacent —CH₂—'s of —CH₂—'s constituting a part of the trivalent hydrocarbon group may be each independently substituted with —O—, —CO—, —S—, —NH—, or —N(Q)—. It is noted that Q represents a substituent, and the substituent represented by Q is preferably an alkyl group, more preferably a linear alkyl group having 1 to 4 carbon atoms, and still more preferably a methyl group or an ethyl group.

As the substituent other than a fluorine atom in which the hydrocarbon group can have, an alkyl group is preferable, a linear alkyl group having 1 to 4 carbon atoms is more preferable, and a methyl group or an ethyl group is still more preferable.

In addition, examples of the heteroatom include a silicon atom, an oxygen atom, and a nitrogen atom, and a silicon atom or an oxygen atom is preferable.

As L^{S1}, an (nₛ+1)-valent linking group which does not have a fluorine atom and has a heteroatom is also preferable.

Examples of the (nₛ+1)-valent linking group represented by one aspect of L^{S1} include a trivalent or higher valent linking group consisting of a combination of a group selected from an ether group and a thioether group, an alkylene group, and a group selected from a tertiary carbon atom and a quaternary carbon atom, which are bonded to the alkylene group.

As the (n+1)-valent linking group, a trivalent linking group consisting of a combination of an alkylene group having 1 to 6 carbon atoms, a tertiary carbon atom bonded to the alkylene group, and two ether groups bonded to the tertiary carbon atom; or a tetravalent linking group consisting of a combination of an alkylene group having 1 to 6 carbon atoms, a quaternary carbon atom bonded to the alkylene group, and three ether groups bonded to the quaternary carbon atom is preferable.

The above-described alkylene group may be linear, branched, or cyclic, and is preferably linear.

As the (nₛ+1)-valent linking group, *-Si(R³⁴)ₘ₂(—O—*)ₘ₁, a group represented by Formula (LA-1), or a group represented by Formula (LA-2) is preferable, and *-Si(R³⁴)ₘ₂(—O—*)ₘ₁ is more preferable. m1 represents 2 or 3. m2 represents 0 or 1. m1+m2 is 3. R³⁴ represents an alkyl group, an alkenyl group, an aryl group, or an alkylene aryl group.

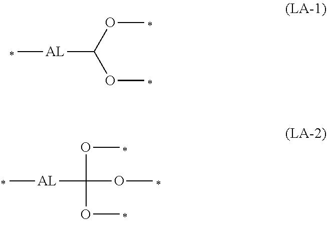

In Formula (LA-1) and Formula (LA-2),
* represents a bonding position, and
AL represents a single bond or an alkylene group having 1 to 6 carbon atoms,

In Formula (S1), nₛ represents an integer of 2 or more.
nₛ preferably represents an integer of 2 to 8, more preferably represents an integer of 3 to 6, and even more preferably represents an integer of 3 to 5.

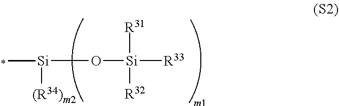

In Formula (S2),
* represents a bonding position,
R³¹, R³², R³³, and R³⁴ each independently represent an alkyl group, an alkenyl group, an aryl group, or an alkylenearyl group, provided that a plurality of R³¹'s may be the same as or different from each other, a plurality of R³²'s may be the same as or different from each other, and a plurality of R³³'s may be the same as or different from each other, and ns m1 represents 2 or 3, m2 represents 0 or 1, and ml+m2 is 3.

R³¹, R³², and R³³ in Formula (S2) have the same meanings as R³¹, R³², and R³³ in Formula (S), respectively, and suitable aspects thereof are also the same.

R³⁴ in Formula (S2) has the same meaning as R³¹, R³², and R³³, and a suitable aspect thereof is also the same.

Hereinafter, the substituent LQ represented by one aspect of Rh will be described in detail.

The substituent LQ is not particularly limited as long as it is a hydrocarbon group having 10 or more carbon atoms, which has two or more terminal methyl groups.

The “terminal methyl group” means a methyl group constituting a terminal of a main chain or side chain of a hydrocarbon group. For example, a linear alkyl group such as an n-propyl group and an n-butyl group is an alkyl group having one terminal methyl group, an isopropyl group is an alkyl group having two terminal methyl groups, and a t-butyl group is an alkyl group having three terminal methyl groups.

For example, an n-decane group is an alkyl group having 10 carbon atoms and one terminal methyl group, and thus does not correspond to the substituent LQ. On the other hand, all of the groups represented by any of Formulae (a-1) to (a-4) have 10 or more carbon atoms and have two or more terminal methyl groups (methyl groups surrounded by a dotted line in the following formulae), and thus correspond to the substituent LQ.

The number of terminal methyl groups contained in the substituent LQ is 2 or more, preferably 3 or more, and more preferably 3 to 10.

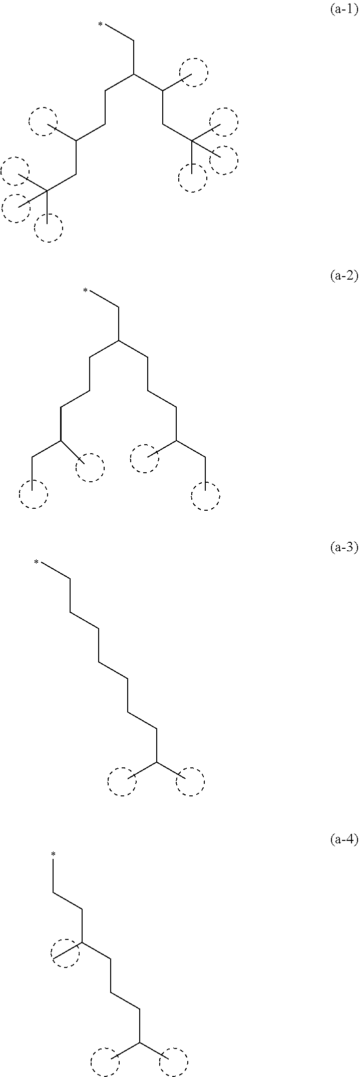

As the hydrocarbon group having 10 or more carbon atoms, which constitutes the substituent LQ, a hydrocarbon group having 10 to 20 carbon atoms is preferable, an alkyl group having 10 to 20 carbon atoms is more preferable, a linear alkyl group having 10 to 18 carbon atoms, a branched alkyl group having 10 to 18 carbon atoms, or a cyclic alkyl group having 10to 20 carbon atoms is still more preferable, and a branched alkyl group having 10 to 18 carbon atoms is particularly preferable.

As the substituent LQ, a group represented by any of Formulae (a-1) to (a-4) is also preferable.

In Formula (A2), R²¹ and R²² have the same meanings as R¹¹ and R¹² in Formula (A1), respectively, and suitable aspects thereof are also the same.

R²³ in Formula (A2) has the same definition as R¹³ in Formula (A1), and the suitable aspect thereof are also the same.

In Formula (A2), L²¹ represents a single bond or a divalent linking group.

Examples of the divalent linking group represented by one aspect of L²¹ include —CO—, —O—, —S—, —C(=S)—, —C(R¹)(R²)—, —C(R³)═C(R⁴)—, —N(R⁵)—, and a divalent group obtained by combining these groups. R¹ to R⁵ each independently represent a hydrogen atom or an alkyl group having 1 to 12 carbon atoms.

As the divalent linking group, —O—, —S—, —CO —O—, —CO—N(R⁵)—, or —CO—S— is preferable, and —CO—O— or —CO—N(R⁵)— is more preferable.

In Formula (A2), L²² represents an (n+1)-valent linking group having a heteroatom.

Examples of the (n+1)-valent linking group having a heteroatom, represented by L²², include a trivalent or higher valent linking group consisting of a combination of a group selected from an ether group and a thioether group, an alkylene group, and a group selected from a tertiary carbon atom and a quaternary carbon atom, which are bonded to the alkylene group.

As the (n+1)-valent linking group having a heteroatom, a trivalent linking group consisting of a combination of an alkylene group having 1 to 6 carbon atoms, a tertiary carbon atom bonded to the alkylene group, and two ether groups bonded to the tertiary carbon atom; or a tetravalent linking group consisting of a combination of an alkylene group having 1 to 6 carbon atoms, a quaternary carbon atom bonded to the alkylene group, and three ether groups bonded to the quaternary carbon atom is preferable.

The above-described alkylene group may be linear, branched, or cyclic, and is preferably linear.

L²² is preferably the group represented by Formula (LA-1) or the group represented by Formula (LA-2).

In Formula (A2), X represents a substituent LR.

The “terminal methyl group” in the substituent LR has the same meaning as the terminal methyl group in the substituent LQ.

The number of terminal methyl groups contained in the substituent LR is 2 or more, preferably 3 to 15, and more preferably 3 to 10.

The number of carbon atoms in the substituent LR is preferably 5 to 30 and more preferably 5 to 20.

From the viewpoint of forming a liquid crystal cured layer in which the occurrence of unevenness is further suppressed, the ratio of the number of terminal methyl groups to the number of carbon atoms in the substituent LR (the number of terminal methyl groups/the number of carbon atoms in the substituent LR) is preferably 0.4 or more and more preferably 0.4 to 0.6.

From the viewpoint of forming a liquid crystal cured layer in which the occurrence of unevenness is further suppressed, the substituent LR is preferably a group represented by any of Formulae (a-1) to (a-6).

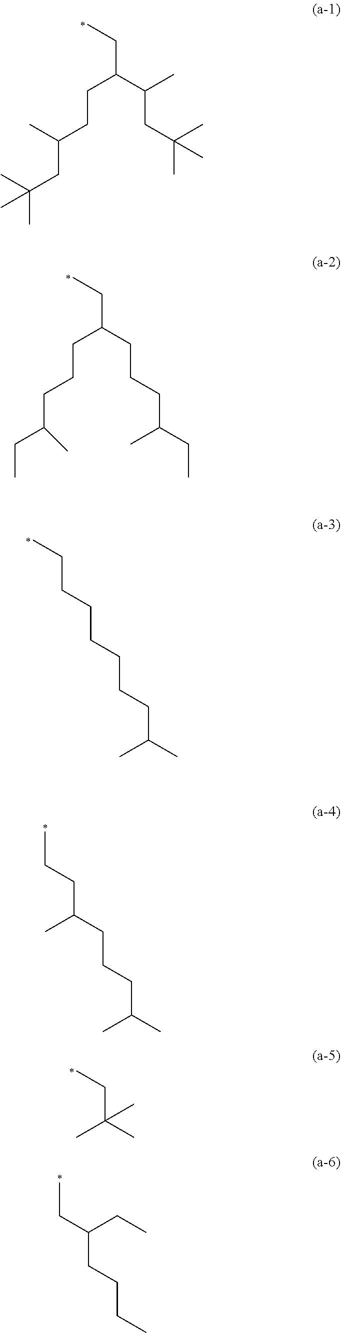

In Formulae (a-1) to (a-6), * represents a bonding position.

In Formula (A2), n represents an integer of 2 or more.

n is preferably an integer of 2 to 10, more preferably an integer of 2 to 8, and still more preferably 2 or 3.

As the repeating unit A, a repeating unit represented by Formula (a1) is preferable.

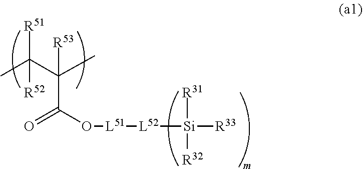

In Formula (a1),
R⁵¹ and R⁵² each independently represent a hydrogen atom or an alkyl group,
R⁵³ represents a hydrogen atom or a substituent,
L⁵¹ represents a single bond or an alkylene group having 1 to 6 carbon atoms,
L⁵² represents an (m+1)-valent linking group not having a fluorine atom,
R³¹, R³², and R³³ each independently represent an alkyl group, an alkenyl group, an aryl group, or an alkylenearyl group, provided that a plurality of R³¹'s may be the same as or different from each other, a plurality of R³²'s may be the same as or different from each other, and a plurality of R³³'s may be the same as or different from each other, and
m represents an integer of 2 or more.

R⁵¹ and R⁵² in Formula (al) have the same meanings as R¹¹ and R¹² in Formula (A1), respectively, and suitable aspects thereof are also the same.

R⁵³ in Formula (al) has the same definition as R¹³ in Formula (A1), and the suitable aspect thereof are also the same.

R³¹, R³², and R³³ in Formula (al) have the same meanings as R³¹, R³², and R³³ in Formula (S), respectively, and suitable aspects thereof are also the same.

In Formula (a1), L⁵¹ represents a single bond or an alkylene group having 1 to 6 carbon atoms.

L⁵¹ is preferably a single bond or a linear alkylene group having 1 to 6 carbon atoms, and more preferably a single bond, a methylene group, an ethylene group, or a propylene group.

In Formula (a1), L⁵² represents an (m+1)-valent linking group not having a fluorine atom.

The (m+1)-valent linking group not having a fluorine atom, represented by L⁵², has the same meaning as the (nₛ+1)-valent linking group not having a fluorine atom, represented by one aspect of L^{S1} in Formula (S1), and a suitable aspect thereof is also the same. In Formula (a1), m represents an integer of 2 or more.

m preferably represents an integer of 2 to 8, more preferably represents an integer of 3 to 6, and even more preferably represents an integer of 3 to 5.

Examples of the repeating unit A include the following repeating units. It is noted that in Examples which will be described later, the repeating unit represented by Formula K-1 is referred to as “K-1”. The same applies to the other repeating units.

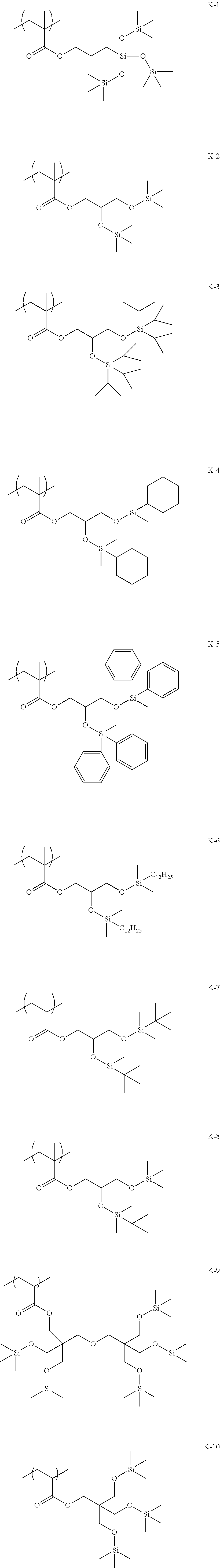

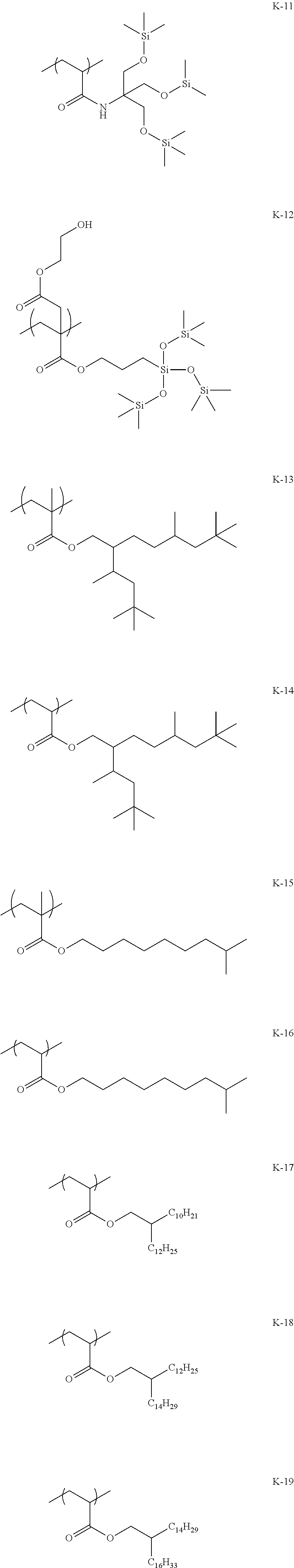

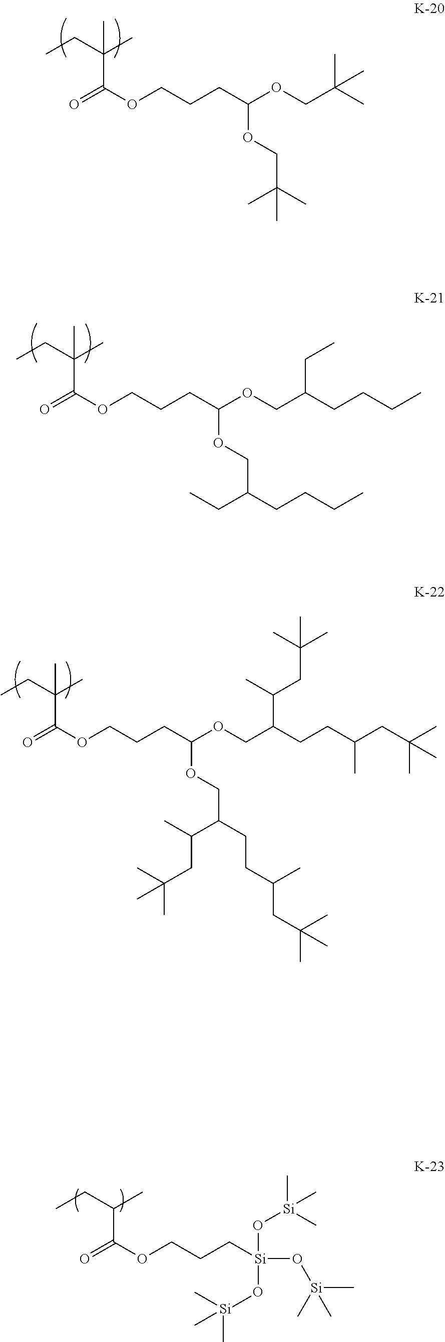

The repeating unit A may be used alone or in combination of two or more types thereof.

The content of the repeating unit A is preferably 10 to 90 mol %, more preferably 30 to 80 mol %, and still more preferably 40 to 70 mol % with respect to all repeating units of the specific copolymer.

### <Repeating Unit B>

The repeating unit B is a repeating unit having the specific group B.

The specific group B is a group having at least one group selected from the group consisting of a hydroxy group, a boronic acid group, a boronic acid ester group, a boronic acid amide group, an epoxy group, an oxetane group, a vinyl group, a styryl group, a (meth)acryloyl group (including a (meth)acrylamide group), and a maleimide group.

The specific group B may be a group having the exemplified group as a part of the structure, or may be the exemplified group itself.

The specific group B is preferably a group having at least one (preferably at least two) group selected from the group consisting of a boronic acid group, a boronic acid ester group, an epoxy group, an oxetane group, a vinyl group, and a (meth)acryloyl group, and more preferably a group having at least one (preferably at least two) group selected from the group consisting of a boronic acid group, a boronic acid ester group, a vinyl group, and a (meth)acryloyl group.

In addition, the specific group B is also preferably a group having at least two groups selected from the group consisting of a hydroxy group, a boronic acid group, a boronic acid ester group, an epoxy group, an oxetane group, a vinyl group, and a (meth)acryloyl group.

In addition, the specific group B is also preferably a group having at least one group selected from the group consisting of a boronic acid group, a boronic acid ester group, an epoxy group, an oxetane group, and a (meth)acryloyl group.

The number of specific groups B contained in the repeating unit B is only required to be 1 or more, and is preferably 1 to 10, more preferably 2 to 10, and still more preferably 2 to 4.

It is noted that the number of the specific groups B indicates the number of specific groups B contained in one type of repeating unit B in a case where the specific polymer contains one type of repeating unit B, and indicates the total number of specific groups B contained in two or more types of repeating units B in a case where the specific polymer includes two or more types of repeating units B. Specifically, in a case where the specific copolymer contains two types of repeating units B, H-1 and H-2, which will be described later, the number of specific groups B contained in the repeating unit is 2.

As the repeating unit B, a repeating unit represented by Formula (B1) is preferable, and a repeating unit represented by any of Formulae (b1) to (b3) is more preferable.

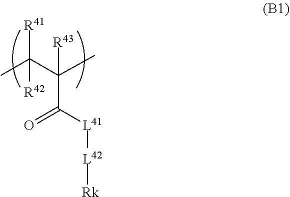

in Formula (B1),
R⁴¹ and R⁴² each independently represent a hydrogen atom or an alkyl group,
R⁴³ represents a hydrogen atom or a substituent,
L⁴¹ represents —O— or —NR^{Z}-, and R^{Z} represents a hydrogen atom or a substituent,
L⁴² represents a single bond or a divalent linking group, and

Rk represents a group having at least one group selected from the group consisting of a boronic acid group, a boronic acid ester group, an epoxy group, an oxetane group, a vinyl group, and a (meth)acryloyl group.

R⁴¹ and R⁴² in Formula (B1) have the same meanings as R¹¹ and R¹² in Formula (A1), respectively, and suitable aspects thereof are also the same.

R⁴³ in Formula (B1) has the same meaning as R¹³ in Formula (A1), and a suitable aspect thereof is also the same.

In Formula (B1), L⁴¹ represents-O-or-NRZ-. RZ represents a hydrogen atom or a substituent,

Regarding-NRZ-represented by one aspect of L⁴¹, the substituent represented by one aspect of RZ is preferably an alkyl group, more preferably a linear alkyl group having 1 to 4 carbon atoms, and still more preferably a methyl group or an ethyl group.

L⁴¹ is preferably-O-or —NH—, and more preferably-O-.

In Formula (B1), L⁴² represents a single bond or a divalent linking group.

Examples of the divalent linking group represented by one aspect of L⁴² include a spacer group represented by SPb1, a mesogen group represented by Mb1, and a group obtained by combining these groups, each of which is shown in Formulae (b2) and (b3), which will be described later.

In Formula (B1), Rk represents a group having at least one group selected from the group consisting of a boronic acid group, a boronic acid ester group, an epoxy group, an oxetane group, a vinyl group, and a (meth)acryloyl group.

Rk is preferably a group having at least one (preferably at least two) group selected from the group consisting of a boronic acid group, a boronic acid ester group, a vinyl group, and a (meth)acryloyl group.

In addition, Rk is preferably a boronic acid group, a boronic acid ester-containing group, an epoxy-containing group, an oxetane-containing group, a vinyl group, or a (meth)acryloyl group, and more preferably a boronic acid group, a boronic acid ester-containing group, a vinyl group, or a (meth)acryloyl group. The boronic acid ester-containing group, the epoxy-containing group, and the oxetane-containing group will be described later.

As the repeating unit B, a repeating unit represented by any of Formulae (b1) to (b3) is also preferable.

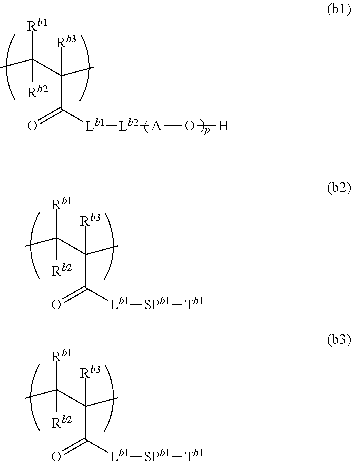

In Formulae (b1) to (b3),
R^{b1} and R^{b2} each independently represent a hydrogen atom or an alkyl group,
R^{b3}'s each independently represent a hydrogen atom or a substituent,
L^{b1}'s each independently represent —O— or —NR^{Zb}-, R^{Zb} represents a hydrogen atom or a substituent,
L^{b2} represents a single bond or a divalent linking group,

A represents an alkylene group, provided that a plurality of A³'s may be the same as or different from each other,
p represents a number of 2 or more,
Sp^{b1} represents a spacer group,
M^{b1} represents a mesogen group, and
T^{b1} and T^{b2} each independently represent a hydroxy group, a boronic acid group, a boronic acid ester-containing group, a boronic acid amide-containing group, an epoxy-containing group, an oxetane-containing group, a vinyl group, a styryl group, a (meth)acryloyl group, or a maleimide group.

R^{b1} and R^{b2} in Formulae (b1) to (b3) have the same meanings as R¹¹ and R¹² in Formula (A1), respectively, and suitable aspects thereof are also the same.

R^{b3} in Formulae (b1) to (b3) has the same meaning as R¹³ in Formula (A1), and a suitable aspect thereof is also the same.

L^{b1} in Formulae (b1) to (b3) has the same meaning as L⁴¹ in Formula (B1), and a suitable aspect thereof is also the same.

Examples of L^{b2} in Formula (b1) include a divalent hydrocarbon group having 1 to 20 carbon atoms, and an alkylene group having 1 to 20 carbon atoms is preferable, and a linear alkylene group having 1 to 18 carbon atoms, a branched alkylene group having 3 to 18 carbon atoms, or a cyclic alkylene group having 3 to 20 carbon atoms is more preferable.

In Formula (b1), A represents an alkylene group. Provided that a plurality of A3's may be the same as or different from each other.

The number of carbon atoms in the alkylene group represented by A is preferably 1 to 4 and more preferably 2 or 3. For example, in a case where A is an alkylene group having 1 carbon atom, -A-O- in Formula (b1) represents an oxymethylene group (—CH₂O—), and in a case where A is an alkylene group having 2 carbon atoms, -A-O- in Formula (b1) represents an oxyethylene group (—CH₂CH₂O—).

The above-described alkylene group may be linear or branched.

-(A-O)ₚ- may be an oxyalkylene group formed by linking an oxymethylene group and an oxypropylene group. The bonding order of the repeating units may be any of a random type or a block type.

In Formula (b1), p represents a number of 2 or more.

The number represented by p is preferably a number from 2 to 1,000 and more preferably a number from 2 to 25.

In Formulae (b2) and (b3), Sp^{b1} represents a spacer group.

The spacer group represented by Sp^{b1} is not particularly limited as long as it is a divalent linking group which does not have a ring structure. Examples of the spacer group represented by Sp^{b1} include a divalent aliphatic hydrocarbon group having 1 to 20 carbon atoms.

The divalent aliphatic hydrocarbon group having 1 to 20 carbon atoms is preferably an alkylene group having 1 to 15 carbon atoms and more preferably an alkylene group having 1 to 8 carbon atoms. Specific examples thereof include a methylene group, an ethylene group, a propylene group, a butylene group, a pentylene group, a hexylene group, a methylhexylene group, and a heptylene group.

In addition, in the spacer group, one —CH₂— or two or more non-adjacent —CH₂—'s of—CH₂-'s constituting a part of the divalent aliphatic hydrocarbon group may be each independently substituted with —O—, —CO—, —S—, —NH—, —CH(Q)—, —C(Q)₂-, or —N(Q)-. R's each independently represent a substituent. The substituent represented by Q is preferably a hydroxy group, an alkyl group, or the specific group B. The above-described alkyl group is preferably a linear alkyl group having 1 to 4 carbon atoms and more preferably a methyl group or an ethyl group.

In Formula (b3), M^{b1} represents a mesogen group.

The mesogenic group represented by M^{b1} is a group representing a main skeleton of liquid crystal molecules contributing to liquid crystal formation. A liquid crystal molecule exhibits liquid crystallinity which is in an intermediate state (mesophase) between a crystal state and an isotropic liquid state.

For mesogenic group, for example, the description on pages 7 to 16 of “Flussige Kristalle in Tabellen II” (VEB Deutsche Verlag fur Grundstoff Industrie, Leipzig, 1984) and the description in Chapter 3 of Liquid Crystal Handbook (Maruzen, 2000) edited by Liquid Crystal Handbook Editing Committee can be referred to.

The mesogen group is preferably a group having at least one cyclic structure selected from the group consisting of an aromatic hydrocarbon group, a heterocyclic group, or an alicyclic group, more preferably a group having an aromatic hydrocarbon group (preferably 1to 5) or a group having an alicyclic group (preferably 1 to 5), and still more preferably a group having 2 to 4 aromatic hydrocarbon groups.

The mesogen group may have a substituent from the viewpoint of improving the alignment degree of the liquid crystal cured layer. The substituent is preferably an alkyl group, an alkoxy group, an alkyl ester group, or an acetyl group and more preferably a methyl group, a tert-butyl group, a methoxy group, or a methyl ester group.

From the viewpoint of further suppressing cissing during the formation of the liquid crystal cured layer, M^{b1} is preferably a mesogen group represented by Formula (M1-A).

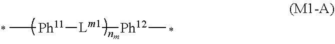

In Formula (M1-A),
* represents a bonding position,
Ph¹¹ and Ph¹² each independently represent a divalent aromatic ring group which may have a substituent, provided that in a case where nm represents an integer of 2 or more, a plurality of Ph¹¹'s may be the same as or different from each other,
L^{m1} represents a single bond or a divalent linking group, provided that in a case where nₘ represents an integer of 2 or more, a plurality of L^{m1}'s may be the same as or different from each other, and
nₘ represents 0 or an integer of 1 or more.

In Formula (M1-A), Ph¹¹ and Ph¹² each independently represent a divalent aromatic ring group which may have a substituent. Provided that in a case where nₘ represents an integer of 2 or more, a plurality of Ph¹¹'s may be the same as or different from each other.

Examples of the divalent aromatic ring group represented by Ph¹¹ and Ph¹² include a group obtained by removing two hydrogen atoms from an aromatic hydrocarbon ring and a group obtained by removing two hydrogen atoms from an aromatic heterocyclic ring.

Examples of the aromatic hydrocarbon ring include a benzene ring, a naphthalene ring, an anthracene ring, and a phenanthroline ring.

Examples of the aromatic heterocyclic ring include a furan ring, a pyrrole ring, a thiophene ring, a pyridine ring, a thiazole ring, and a benzothiazole ring.

Among these, the divalent aromatic ring group represented by Ph¹¹ and Ph¹² is preferably a group obtained by removing two hydrogen atoms from a benzene ring (for example, a 1,4-phenyl group).

In addition, the substituent which may be contained in the divalent aromatic ring group is preferably an alkyl ester group, an alkyl group, or an acetyl group, more preferably a methyl ester group or a linear alkyl group having 1 to 4 carbon atoms, and still more preferably a methyl group or an ethyl group.

In Formula (M1-A), L^{m1} represents a single bond or a divalent linking group. Provided that in a case where nₘ represents an integer of 2 or more, a plurality of L^{m1}'s may be the same as or different from each other.

Examples of the divalent linking group represented by one aspect of L^{m1} include —CO—, —O—, —S—, —C(═S)—, —C(R¹)(R²)-, —C(R³)═C(R⁴)-, —N(R⁵)-, and a group obtained by combining these groups. R¹ to R⁵ each independently represent a hydrogen atom, a fluorine atom, or an alkyl group having 1 to 12 carbon atoms.

In Formula (M1-A), nₘ represents 0 or an integer of 1 or more.

nₘ is preferably an integer of 1 to 10. In addition, nₘ is also preferably an integer of 0 to 10.

In Formulae (b2) and (b3), T^{b1} and T^{b2} each independently represent a hydroxy group, a boronic acid group, a boronic acid ester-containing group, a boronic acid amide-containing group, an epoxy-containing group, an oxetane-containing group, a vinyl group, a styryl group, a (meth)acryloyl group, or a maleimide group.

As T^{b1} and T^{b2}, a boronic acid group, a boronic acid ester-containing group, a boronic acid amide-containing group, a vinyl group, a styryl group, a (meth)acryloyl group, or a maleimide group is preferable.

As T^{b1}, an epoxy-containing group, an oxetane-containing group, a vinyl group, a (meth)acryloyl group, or a maleimide group is preferable, and a vinyl group or a (meth)acryloyl group is more preferable.

As T^{b2}, a hydroxy group, a boronic acid group, a boronic acid ester-containing group, a boronic acid amide-containing group, or a (meth)acryloyl group is preferable, a boronic acid group, a boronic acid ester-containing group, a boronic acid amide-containing group, or a (meth)acryloyl group is more preferable, and a boronic acid group, a boronic acid ester-containing group, or a (meth)acryloyl group is still more preferable.

The boronic acid ester-containing group is a group having a boronic acid ester group in a structure of a part of the group, and is preferably a group represented by *-B(—OR)₂. * represents a bonding position. R represents a substituent. The above-described substituent is preferably an alkyl group. R's may be bonded to each other to form a ring. Examples of the boronic acid ester-containing group include a dioxaborolane group and a dioxaborinane group.

The boronic acid amide-containing group is a group having a boronic acid amide group in a structure of a part of the group, and is preferably a group represented by *-B(-NR^{N}₂)₂. * represents a bonding position. RN's each independently represent a hydrogen atom or a substituent. The above-described substituent is preferably an alkyl group. RN's may be bonded to each other to form a ring.

The epoxy-containing group is an epoxy group itself or a group having an epoxy group in a structure of a part of the group. Examples of the epoxy-containing group include an epoxy group, a glycidyl ether group, and an alicyclic epoxy group. The alicyclic epoxy group is a fused polycyclic group formed by fusion of an alicyclic group and an epoxy group. Examples of the alicyclic epoxy group include an epoxycyclopentyl group and an epoxycyclohexyl group.

The oxetane-containing group is an oxetane group (oxetane ring group) itself or a group having an oxetane group in a structure of a part of the group. Examples of the oxetane-containing group include an oxetane group and an oxetanyl group.

As the epoxy-containing group and the oxetane-containing group, a group represented by any of Formulae (C1) to (C3) is preferable.

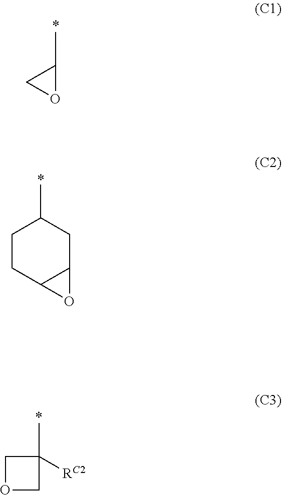

In Formulae (C1) to (C3),
* represents a bonding position,
R^{C2} represents a hydrogen atom, a methyl group, or an ethyl group.

Examples of the repeating unit B include the following repeating units.

s and t in the following repeating units each independently represent a number of 1 or more.

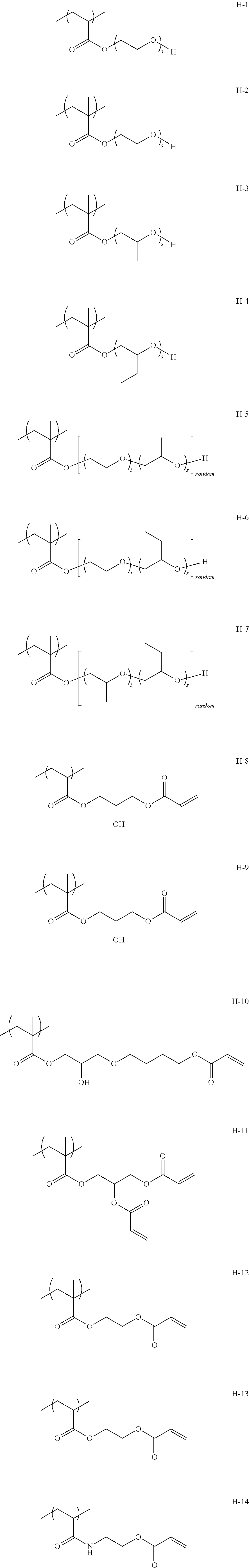

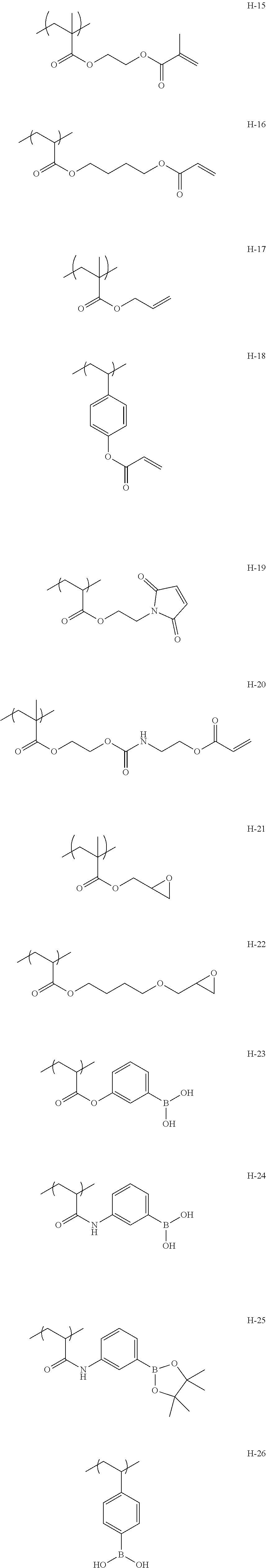

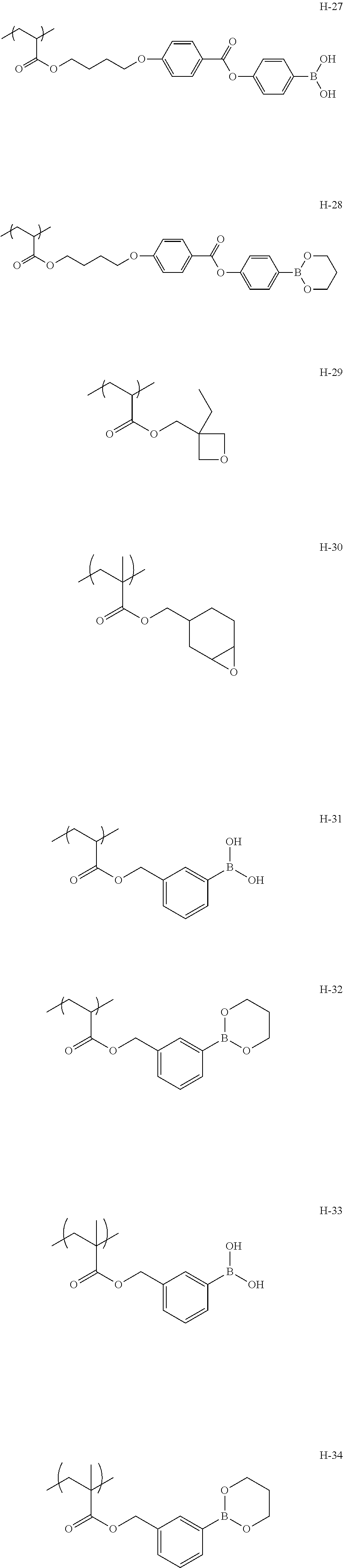

The repeating unit B may be used alone or in combination of two or more types, and it is preferable to use two or more types and more preferable to use two or three types. In addition, in a case where two or more types of repeating units B are used, it is preferable that the specific groups B contained in the respective repeating units B are different from each other.

The content of the repeating unit B is preferably 10 to 90 mol %, more preferably 20 to 70 mol %, and still more preferably 25 to 60 mol % with respect to all repeating units of the specific copolymer.

### <Other Repeating Units>

The specific copolymer may contain other repeating units in addition to the above-described repeating unit A and repeating unit B.

Examples of the other repeating units include repeating units derived from compounds such as (meth)acrylic acid, an acrylic acid ester compound, a methacrylic acid ester compound, a maleimide compound, an acrylamide compound, acrylonitrile, a maleic acid anhydride, a styrene compound, and a vinyl compound.

In addition, from the viewpoint of improving the adhesiveness, as the other repeating units, a repeating unit derived from alkoxypolyalkylene glycol acrylate such as methoxytetraethylene glycol acrylate and methoxypolyethylene glycol acrylate is also preferable.

The other repeating units may be used alone or in combination of two or more types thereof.

The content of the other repeating units is preferably 0.1 to 30 mol %, more preferably 0.1 to 10 mol %, and still more preferably 0.1 to 5 mol %.

The total content of the repeating unit A and the repeating unit B is preferably 80 to 100 mol %, more preferably 90 to 100 mol %, and still more preferably 95 to 100 mol % with respect to all repeating units of the specific copolymer.

The total content of the repeating unit A, the repeating unit B, and the repeating unit derived from (meth)acrylic acid is preferably 90 to 100 mol % and more preferably 99 to 100 mol % with respect to all repeating units of the specific copolymer.

### <Content>

The specific copolymer may be used alone or in combination of two or more types thereof.

The content of the specific copolymer is preferably 0.01% to 10% by mass, more preferably 0.02% to 1% by mass, and still more preferably 0.04% to 0.5% by mass with respect to the total solid content (100% by mass) of the liquid crystal composition.

### <Molecular Weight>

The weight-average molecular weight (Mw) of the specific copolymer is preferably 2,000 to 1,000,000, and from the viewpoint of further improving the leveling properties of the liquid crystal composition, it is more preferably 8,000 or more and less than 80,000.

The weight-average molecular weight is a value measured by gel permeation chromatography (GPC).
Solvent (eluent): tetrahydrofuran (THF)
Apparatus name: EcoSEC HLC-8320GPC (manufactured by ToSoh Corporation)
Column: three columns of TSKgel SuperHZM-H, TSKgel SuperHZ4000, and TSKgel SuperHZ200 (all manufactured by ToSoh Corporation) are connected and used.
Column Temperature: 40° C.
Sample concentration: 0.1% by mass
Flow rate: 0.35 mL/min
Calibration curve: TSK standard polystyrene (manufactured by ToSoh Corporation), calibration curves of six samples with Mw of 706,000 to 1,013 (Mw/Mn=1.03 to 1.06) are used.

### Liquid Crystal Compound

The liquid crystal composition according to the embodiment of the present invention contains a liquid crystal compound.

The type of the liquid crystal compound is not particularly limited. In general, the liquid crystal compound can be classified into a rod-like type and a disk-like type according to the shape thereof. Furthermore, there are a low-molecular-weight type and a high-molecular-weight type for each type. The term, high-molecular-weight type, generally refers to having a degree of polymerization of 100 or more (Polymer Physics-Phase Transition Dynamics, by Masao Doi, page 2, published by Iwanami Shoten, Publishers, 1992).

As the liquid crystal compound, a rod-like liquid crystal compound or a disk-like liquid crystal compound (discotic liquid crystal compound) is preferable. The liquid crystal compound may be a mixture of two or more types of rod-like liquid crystal compounds, a mixture of two or more types of disk-like liquid crystal compounds, or a mixture of a rod-like liquid crystal compound and a disk-like liquid crystal compound.

As the liquid crystal compound, a polymerizable liquid crystal compound having a polymerizable group is preferable.

The polymerizable liquid crystal compound is preferably at least one polymerizable liquid crystal compound selected from the group consisting of a polymerizable rod-like liquid crystal compound and a polymerizable disk-like liquid crystal compound.

Examples of the polymerizable group include a (meth)acryloyl group, an epoxy group, and a vinyl group. By polymerizing the liquid crystal compound having the polymerizable group, the alignment of the liquid crystal compound can be immobilized. It is noted that the liquid crystal compound does not need to exhibit liquid crystallinity after being immobilized by polymerization.

As the rod-like liquid crystal compound, compounds described in the claim 1 of JP1999-513019A (JP-H11-513019A) or paragraphs [0026] to [0098] of JP2005-289980A are preferable.

As the disk-like liquid crystal compound, disk-like liquid crystal compounds described in paragraphs [0020] to [0067] of JP2007-108732A or paragraphs [0013] to [0018] of JP2010-244038A are preferable.

In addition, a liquid crystal compound having reverse wavelength dispersibility may be used as the liquid crystal compound.

The liquid crystal compound may be used alone or in combination of two or more types thereof.

The content of the liquid crystal compound is preferably in a range of 10% to 99% by mass and more preferably in a range of 50% to 95% by mass with respect to the total solid content (100% by mass) of the liquid crystal compound.

### Solvent

From the viewpoint of workability and the like, the liquid crystal composition according to the embodiment of the present invention preferably contains a solvent.

Examples of the solvent include organic solvents such as ketones (for example, acetone, 2-butanone, methyl ethyl ketone, methyl isobutyl ketone, cyclopentanone, and cyclohexanone), ethers (for example, dioxane, tetrahydrofuran, tetrahydropyran, dioxolane, tetrahydrofurfuryl alcohol, propylene glycol monomethyl ether acetate, and cyclopentyl methyl ether), aliphatic hydrocarbons (for example, hexane), alicyclic hydrocarbons (for example, cyclohexane), aromatic hydrocarbons (for example, benzene, toluene, xylene, and trimethylbenzene), halogenated carbons (for example, dichloromethane, trichloromethane (chloroform), dichloroethane, dichlorobenzene, and chlorotoluene), esters (for example, methyl acetate, ethyl acetate, ethyl propionate, butyl acetate, and diethyl carbonate), alcohols (for example, methanol, ethanol, isopropanol, butanol, and cyclohexanol), cellosolves (for example, methyl cellosolve, ethyl cellosolve, and 1,2-dimethoxyethane), cellosolve acetates, sulfoxides (for example, dimethyl sulfoxide), amides (for example, dimethylformamide, dimethylacetamide, N-methylpyrrolidone, N-ethylpyrrolidone, and 1,3-dimethyl-2-imidazolidinone), and heterocyclic compounds (for example, pyridine), and water.

The solvent may be used alone or in combination of two or more types thereof.

From the viewpoints that the aligning properties of the liquid crystal cured layer formed of the liquid crystal composition are further improved and the heat resistance is further improved, the solvent is preferably an organic solvent, and more preferably ketones and/or esters.

### Polymerization Initiator

The liquid crystal composition according to the embodiment of the present invention may contain a polymerization initiator.

As the polymerization initiator, a compound having photosensitivity (that is, a photopolymerization initiator) is preferable.

Examples of the photopolymerization initiator include an a-carbonyl compound, acyloin ether, an a-hydrocarbon-substituted aromatic acyloin compound, a polynuclear quinone compound, a combination of a triarylimidazole dimer and p-aminophenyl ketone, acridine, a phenazine compound, an oxadiazole compound, an o-acyl oxime compound, an acylphosphine oxide compound, and an oxime-type polymerization initiator.

Examples of a commercially available product of the photopolymerization initiator include IRGACURE-184, IRGACURE-907, IRGACURE-369, IRGACURE-651, IRGACURE (Ominirad)-819, IRGACURE-OXE-01, and IRGACURE-OXE-02, manufactured by BASF SE.

The polymerization initiator may be used alone or in combination of two or more types thereof.

In a case where the liquid crystal composition contains a polymerization initiator, the content of the polymerization initiator is preferably in a range of 0.01% to 30% by mass and more preferably in a range of 0.1% to 15% by mass with respect to the total solid content (100% by mass) of the liquid crystal composition.

### Chiral Agent

The liquid crystal composition may include a chiral agent.

The chiral agent may be selected according to the purpose since the induced helical twisted direction or helical pitch varies depending on the compound.

Examples of the chiral agent include a well-known compound (for example, Liquid Crystal Device Handbook (No. 142 Committee of Japan Society for the Promotion of Science, 1989), Chapter 3, Article 4-3, a chiral agent for twisted nematic (TN) or super twisted nematic (STN), p. 199), isosorbide, or an isomannide derivative.

The chiral agent may be any of a chiral compound containing an asymmetric carbon atom, an axially chiral compound or a planar chiral compound chiral agent, which does not contain an asymmetric carbon atom. Examples of the axially chiral compound or the planar chiral compound include binaphthyl, helicene, paracyclophane, and a derivative thereof. The chiral agent may also have a polymerizable group.

The above-described polymerizable group is preferably an unsaturated polymerizable group, an epoxy group, or an aziridinyl group, more preferably an unsaturated polymerizable group, and still more preferably an ethylenically unsaturated polymerizable group. The chiral agent may also have a photoisomerization moiety.

The photoisomerization moiety is preferably a cinnamoyl moiety, a chalcone moiety, an azobenzene moiety, or a stilbene moiety, and more preferably a cinnamoyl moiety, a chalcone moiety, or a stilbene moiety.

Examples of the chiral agent include optically active isosorbide derivatives described in paragraphs [0015] to [0049] of JP2003-313187A, optically active isomannide derivatives described in paragraphs [0015] to [0057] of JP2003-313188A, optically active polyester/amide described in paragraphs [0015] to [0052] of JP2003-313292A, and chiral agents described in paragraphs [0012] to [0053] of WO2018/194157A.

The chiral agent may be used alone or in combination of two or more types thereof.

In a case where the liquid crystal composition contains the chiral agent, from the viewpoint that the liquid crystal compound is easily aligned uniformly, the content of chiral agent is preferably 5.0% by mass or less, more preferably 3.0% by mass or less, still more preferably 2.0% by mass or less, particularly preferably less than 1.0% by mass, with respect to the total mass of the liquid crystal compound. The lower limit of the content of the chiral agent B is not particularly limited, and is preferably 0.01% by mass or more, more preferably 0.02% by mass or more, and still more preferably 0.05% by mass or more.

In a case where a liquid crystal cured layer having a plurality of alignment states in one layer is formed, as the chiral agent used in the liquid crystal composition, it is preferable to use two or more types of chiral agents including a chiral agent A and a chiral agent B that induces a helix in a direction opposite to that of the chiral agent A. For example, in a case where the helix induced by the chiral agent A is right-handed, the helix induced by the chiral agent B is left-handed.

The liquid crystal composition may contain other components in addition to the above-described various components.

Examples of the other components include a polyfunctional monomer, an alignment assistant such as a horizontal alignment agent and a vertical alignment agent, an adhesion improver, and a plasticizer.

### Liquid Crystal Cured Layer

The liquid crystal cured layer of an embodiment of the present invention is a liquid crystal cured layer obtained by immobilizing the alignment state of the above-mentioned liquid crystal composition of the embodiment of the present invention.

Examples of a method for forming the liquid crystal cured layer include a method in which the above-mentioned liquid crystal composition of the embodiment of the present invention is used to cause a desired alignment state, which is then immobilized by polymerization.

The polymerization conditions are not particularly limited, but in the polymerization by irradiation with light, ultraviolet rays are preferably used. The irradiation dose of light is preferably 10 mJ/cm² to 50 J/cm², more preferably 20 mJ/cm² to 5 J/cm², even more preferably 30 mJ/cm² to 3 J/cm², and particularly preferably 50 to 1,000 mJ/cm². In addition, in order to promote the polymerization reaction, the light irradiation may be performed under heating conditions.

It is noted that the liquid crystal cured layer can be formed on any of supports or alignment films in the optical film which will be described later or a polarizer in the polarizing plate which will be described later.

The alignment state of the liquid crystal compound in the liquid crystal cured layer of the embodiment of the present invention may be any one of horizontal alignment, vertical alignment, tilt alignment, and twist alignment.

In addition, a plurality of alignment states may be provided in one layer as in a liquid crystal cured layer described in WO2021/033640A, having a first region in which an alignment state of a liquid crystal compound twist-aligned along a helical axis extending along a thickness direction is immobilized and a second region in which an alignment state of a homogeneously aligned liquid crystal compound is immobilized, along a thickness direction.

It is noted that in the present specification, the “horizontal alignment” means that the main surface of a liquid crystal cured layer (or in a case where the liquid crystal cured layer is formed on a member such as a support and an alignment film, a surface of the member) and the major axis direction of the liquid crystal compound are parallel to each other. Incidentally, it is not required for both the main surface of a liquid crystal cured layer and the major axis direction of the liquid crystal compound to be strictly parallel, and in the present specification, the expression means that both the main surface of a liquid crystal cured layer and the major axis direction of the liquid crystal compound are aligned at an angle formed by the major axis direction of the liquid crystal compound and the main surface of the liquid crystal cured layer of less than 10°.

In addition, in the present specification, the “vertical alignment” means that a normal line with respect to a main surface of the liquid crystal cured layer is parallel to a major axis direction of the liquid crystal compound. Incidentally, it is not required for both the main surface of a liquid crystal cured layer and the major axis direction of the liquid crystal compound to be strictly parallel, and in the present specification, the expression means that both the normal line with respect to the main surface of a liquid crystal cured layer and the major axis direction of the liquid crystal compound are aligned at an angle formed by the major axis direction of the liquid crystal compound and the normal line with respect to the main surface of the liquid crystal cured layer of less than 10°.

The liquid crystal cured layer according to the embodiment of the present invention is preferably an optically anisotropic layer.

Examples of the optically anisotropic layer include a positive A-plate, a positive C-plate, and an optically anisotropic layer (hereinafter, this aspect is referred to as an “optically anisotropic layer A”) including a first region in which an alignment state of a liquid crystal compound twist-aligned along a helical axis extending along a thickness direction is immobilized and a second region in which an alignment state of a homogeneously aligned liquid crystal compound is immobilized, along the thickness direction.

Here, the positive A-plate (A-plate which is positive) and the positive C-plate (C-plate which is positive) are defined as follows.

In a case where a refractive index in a film in-plane slow axis direction (in a direction in which an in-plane refractive index is maximum) is defined as nx, a refractive index in an in-plane direction orthogonal to the in-plane slow axis is defined as ny, and a refractive index in a thickness direction is defined as nz, the positive A-plate satisfies the relationship of Expression (A1), and the positive C-plate satisfies the relationship of Expression (C1). It is noted that the positive A-plate has Rth of a positive value, and the positive C-plate has Rth of a negative value.

$$n x > ny \approx nz \qquad Expression ( A1 )$$

$$nz > nx \approx ny \qquad Expression ( C1 )$$

It is noted that the symbol “˜” encompasses not only a case where the values of both sides are completely the same but also a case where the values of both sides are substantially the same.

In the expression, “substantially the same”, with regard to the positive A plate, for example, a case where (ny−nz)×d (in which d is the thickness of a film) is −10 to 10 nm, and preferably −5 to 5 nm is also included in “ny˜nz”, and a case where (nx-nz) x d is −10 to 10 nm, and preferably −5 to 5 nm is also included in “nx˜nz”. In addition, with regard to the positive C plate, for example, a case where (nx−ny)×d (in which d is the thickness of a film) is 0 to 10 nm, and preferably 0 to 5 nm is also included in “nx˜ny”.

In a case where the liquid crystal cured layer of the embodiment of the present invention is a positive A plate, the Re (550) is preferably 100 to 180 nm, more preferably 120 to 160 nm, still more preferably 130 to 150 nm, and particularly preferably 130 to 145 nm, from the viewpoint that the liquid crystal cured layer functions as a λ/4 plate.

Here, the “λ/4 plate” is a plate having a λ/4 function, and specifically, a plate having a function of converting linearly polarized light having a specific wavelength into circularly polarized light (or circularly polarized light into linearly polarized light).

An optically anisotropic layer (optically anisotropic layer A) having a first region in which an alignment state of a liquid crystal compound twist-aligned along a helical axis extending along a thickness direction is immobilized and a second region in which an alignment state of a homogeneously aligned liquid crystal compound is immobilized, along the thickness direction, will be described in detail.

In a case where the thickness of the first region of the optically anisotropic layer is defined as d1 (nm) and the refractive index anisotropy of the first region measured at a wavelength of 550 nm is defined as Δn1, from the viewpoint that an optically anisotropic layer can be suitably applied to a circularly polarizing plate, the first region preferably satisfies Expression (1-1).

$$100 nm \leq Δ n 1 d 1 \leq 240 nm \qquad Expression ( 1 - 1 )$$

Above all, the first region more preferably satisfies Expression (1-2) and still more preferably satisfies Expression (1-3).

$$120 nm \leq Δ n 1 d 1 \leq 220 nm \qquad Expression ( 1 - 2 )$$

$$140 nm \leq Δ n 1 d 1 \leq 200 nm \qquad Expression ( 1 - 3 )$$

It is noted that the refractive index anisotropy Δn1 means a refractive index anisotropy of the first region.

The absolute value of the twisted angle of the liquid crystal compound in the first region is not particularly limited and is preferably 60° to 120° and more preferably 70° to 110° from the viewpoint that an optically anisotropic layer can be suitably applied to a circularly polarizing plate. The twisted angle is measured using Axoscan of Axometrics, Inc. and using device analysis software of Axometrics, Inc.

In addition, in a case where the thickness of the second region of the optically anisotropic layer A is defined as d2 (nm) and the refractive index anisotropy of the second region measured at a wavelength of 550 nm is defined as Δn2, from the viewpoint that an optically anisotropic layer can be suitably applied to a circularly polarizing plate, the second region preferably satisfies Expression (2-1).

$$100 nm \leq Δ n 2 d 2 \leq 240 nm \qquad Expression ( 2 - 1 )$$

Above all, the second region more preferably satisfies Expression (2-2) and still more preferably satisfies Expression (2-3).

$$120 nm \leq Δ n 2 d 2 \leq 220 nm \qquad Expression ( 2 - 2 )$$

$$140 nm \leq Δ n 2 d 2 \leq 200 nm \qquad Expression ( 2 - 3 )$$

The refractive index anisotropy Δn2 means a refractive index anisotropy of the second region.

### Light Absorption Anisotropic Layer

The liquid crystal cured layer according to the embodiment of the present invention may be a light absorption anisotropic layer.

The light absorption anisotropic layer is a liquid crystal cured layer containing a dichroic substance.

The light absorption anisotropic layer is more preferably a layer obtained by immobilizing vertically the alignment states of the liquid crystal compound and the dichroic substance (a vertically aligned layer).

Examples of the light absorption anisotropic layer include the light absorption anisotropic layers described in paragraphs [0014] to [0147] of WO2021/131792A, paragraphs [0024] to [0186] of WO2021/230019A, and paragraphs [0015] to [0247] of WO2022/138555A.

### <Dichroic Substance>

The dichroic substance denotes a substance having different absorbances depending on the direction. In addition, the dichroic substance may or may not exhibit liquid crystallinity.

The dichroic substance is not particularly limited, and examples thereof include a visible light absorbing substance (dichroic coloring agent), a light emitting substance (fluorescent substance and phosphorescent substance), an ultraviolet absorbing substance, an infrared absorbing substance, a non-linear optical substance, a carbon nanotube, and an inorganic substance (for example, quantum rod). Further, dichroic substances (dichroic coloring agents) known in the related art can be used.

Specific examples thereof include dichroic substances described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-014883A, paragraphs [0012] to [0029] of JP2013-109090A, paragraphs [0009] to [0017] of JP2013-101328A, paragraphs [0051] to [0065] of JP2013-037353A, paragraphs [0049] to [0073] of JP2012-063387A, paragraphs [0016] to [0018] of JP1999-305036A (JP-H11-305036A), paragraphs [0009] to [0011] of JP2001-133630A, [0030] to [0169] of JP2011-215337A, paragraphs [0021] to [0075] of JP2010-106242A, paragraphs [0011] to [0025] of JP2010-215846A, paragraphs [0017] to [0069] of JP2011-048311A, paragraphs [0013] to [0033] of JP2011-213610A, paragraphs [0074] to [0246] of JP2011-237513A, paragraphs [0005] to [0051] of JP2016-006502A, paragraphs [0014] to [0032] of JP2018-053167A, paragraphs [0014] to [0033] of JP2020-011716A, paragraphs [0005] to [0041] of WO2016/060173A, paragraphs [0008] to [0062] of WO2016/136561A, paragraphs [0014] to [0033] of WO2017/154835A, paragraphs [0014] to [0033] of WO2017/154695A, paragraphs [0013] to [0037] of WO2017/195833A, paragraphs [0014] to [0034] of WO2018/164252A, paragraphs [0021] to [0030] of WO2018/186503A, paragraphs [0043] to [0063] of WO2019/189345A, paragraphs [0043] to [0085] of WO2019/225468A, paragraphs [0050] to [0074] of WO2020/004106A, and paragraphs [0015] to [0038] of WO2021/044843A.

As the dichroic substance, a dichroic azo coloring agent compound is preferable.

The dichroic azo coloring agent compound means an azo coloring agent compound having different absorbances depending on directions.

The dichroic azo coloring agent compound may or may not exhibit liquid crystallinity. In a case where the dichroic azo coloring agent compound exhibits liquid crystallinity, it may exhibit any of nematic properties or smectic properties may be exhibited. The temperature range in which the liquid crystal phase is exhibited is preferably room temperature (approximately 20° C. to 28° C.) to 300° C., and from the viewpoints of handleability and production suitability, more preferably 50° C. to 200° C.

In the present invention, from the viewpoint of tint adjustment, it is preferable to use at least at least one coloring agent compound (first dichroic azo coloring agent compound) having a maximal absorption wavelength in a wavelength range of 560 to 700 nm and at least one coloring agent compound (second dichroic azo coloring agent compound) having a maximal absorption wavelength in a wavelength range of 455 nm or more and less than 560 nm.

In the present invention, three or more dichroic azo coloring agent compounds may be used in combination. For example, from the viewpoint of making the light absorption anisotropic layer close to black, it is preferable to use the first dichroic azo coloring agent compound, the second dichroic azo coloring agent compound, and at least one coloring agent compound (third dichroic azo coloring agent compound) having a maximal absorption wavelength in a wavelength range of 380 nm or more and less than 455 nm in combination. The dichroic azo coloring agent compound preferably has a crosslinkable group.

Examples of the crosslinkable group include a (meth)acryloyl group, an epoxy group, an oxetanyl group, and a styryl group, and a (meth)acryloyl group is preferable.

The content of the dichroic substance is not particularly limited, but due to the reason that the alignment degree of the formed light absorption anisotropic layer is further increased, it is preferably 3% by mass or more, more preferably 8% by mass or more, still more preferably 10% by mass or more, and particularly preferably 10% to 30% by mass with respect to the total mass of the light absorption anisotropic layer. In a case where a plurality of dichroic substances are used in combination, the total amount of the plurality of dichroic substances is preferably within the above range.

In particular, from the reason that the difference in the alignment degrees of the light absorption anisotropic layer at the wavelengths of 450 nm, 550 nm, and 650 nm to be 0.025 or less is facilitated, the content of the first dichroic azo coloring agent compound is preferably 9% to 12% by mass with respect to the total mass of the light absorption anisotropic layer, the content of the second dichroic azo coloring agent compound is preferably 1% to 2% by mass with respect to the total mass of the light absorption anisotropic layer, and the content of the third dichroic azo coloring agent compound is preferably 4% to 7% by mass with respect to the total mass of the light absorption anisotropic layer.

The light absorption anisotropic layer has a transmittance central axis. Here, the transmittance central axis is a direction in which the highest transmittance is exhibited in a case where the transmittance is measured by changing a polar angle and an azimuthal angle with respect to a normal direction of a surface of the light absorption anisotropic layer.

Specifically, the Mueller matrix at a wavelength of 550 nm is measured using AxoScan OPMF-2 (manufactured by Opto Science, Inc.). More specifically, in the measurement, an azimuthal angle at which the transmittance central axis is inclined is first searched for, the Mueller matrix at a wavelength of 550 nm is measured while the polar angle which is the angle with respect to the normal direction of the surface of the light absorption anisotropic layer is changed from −70° to 70° at intervals of 1° in the surface (the plane that has the transmittance central axis and is orthogonal to the layer surface) having the normal direction of the light absorption anisotropic layer along the azimuthal angle, and the transmittance of the light absorption anisotropic layer is derived. As a result, the direction in which the highest transmittance is exhibited is defined as the transmittance central axis.

The transmittance central axis is also an absorption axis of the light absorption anisotropic layer, and often corresponds to a direction (the major axis direction of the molecule) of the absorption axis of the dichroic substance contained in the light absorption anisotropic layer. As described above, in a case where light is incident from a direction inclined with respect to the transmittance central axis, the transmittance central axis can function as an absorption axis.

### Optical Film

The optical film of an embodiment of the present invention is an optical film having the liquid crystal cured layer of the embodiment of the present invention.

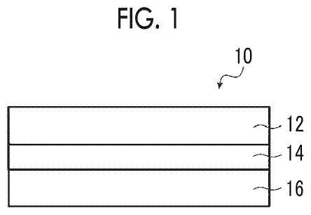

The structure of the optical film will be described with reference to FIG. 1. FIG. 1 is a schematic cross-sectional view showing an example of the optical film.

Furthermore, FIG. 1 is a schematic view, and the thicknesses relationship, the positional relationship, and the like among the respective layers are not necessarily consistent with actual ones, and either of the support shown in FIG. 1 and an alignment film are optional constitutional members.

An optical film 10 shown in FIG. 1 has a support 16, an alignment film 14, and a liquid crystal cured layer 12 as the cured product of the liquid crystal composition of the embodiment of the present invention in this order.

In addition, the liquid crystal cured layer 12 may be a laminate of two or more different liquid crystal cured layers. For example, in a case where the polarizing plate of the embodiment of the present invention which will be described later is used as a circularly polarizing plate or in a case where the optical film of the embodiment of the present invention is used as an optical compensation film for an in-plane-switching (IPS) mode or a fringe-field-switching (FFS) mode liquid crystal display device, the liquid crystal cured layer is preferably a laminate of a positive A plate and a positive C plate.

In addition, the liquid crystal cured layer may be peeled from the support or the alignment film, and the liquid crystal cured layer may be used alone as an optical film.

Hereinafter, various members used for the optical film will be described in detail.

### Liquid Crystal Cured Layer

The liquid crystal cured layer contained in the optical film of the embodiment of the present invention is the above-mentioned liquid crystal cured layer of the embodiment of the present invention.

The thickness of the liquid crystal cured layer in the optical film is not particularly limited, but is preferably 0.1 to 10 μm and more preferably 0.5 to 5 μm.

### Support

The optical film may have a support as a base material for forming a liquid crystal cured layer as described above.

The above-described support is preferably transparent. Specifically, the light transmittance is preferably 80% or more.

Examples of the above-described support include a glass substrate and a polymer film. Examples of the material for the polymer film include cellulose-based polymers; acrylic polymers having an acrylic ester polymer such as polymethyl methacrylate and a lactone ring-containing polymer; thermoplastic norbornene-based polymers; polycarbonate-based polymers; polyester-based polymers such as polyethylene terephthalate and polyethylene naphthalate; styrene-based polymers such as polystyrene and an acrylonitrile-styrene copolymer (AS resin); polyolefin-based polymers such as polyethylene, polypropylene, and an ethylene-propylene copolymer; vinyl chloride-based polymers; amide-based polymers such as nylon and aromatic polyamide; imide-based polymers; sulfone-based polymers; polyether sulfone-based polymers; polyether ether ketone-based polymers; polyphenylene sulfide-based polymers; vinylidene chloride-based polymers; vinyl alcohol-based polymers; vinyl butyral-based polymers; arylate-based polymers; polyoxymethylene-based polymers; epoxy-based polymers; and polymers obtained by mixing these polymers.

In addition, an aspect in which a polarizer which will be described later also functions as such a support is also available.

A thickness of the support is not particularly limited, but is preferably 5 to 100 μm, and more preferably 5 to 50 μm. The support is preferably peelable.

### Alignment Film

In the optical film, the liquid crystal cured layer is preferably formed on a surface of an alignment film. In a case where the optical film has any of the above-mentioned supports, it is preferable that the alignment film may be sandwiched between the support and the liquid crystal cured layer. In addition, an aspect in which the above-mentioned support may also function as an alignment film is also available.

The alignment film is not particularly limited as long as it has a function of aligning the polymerizable liquid crystal compound included in the composition.

Generally, the alignment film contains a polymer as a main component. Polymer materials for the alignment film are described in many documents, and many commercially available products thereof can be used.

As the polymer material for the alignment film, a polyvinyl alcohol, a polyimide, or a derivative thereof is preferable, and a modified or unmodified polyvinyl alcohol is more preferable.

Since an object does not come into contact with a surface of the alignment film upon formation of the alignment film and the deterioration of a surface condition can be prevented, it is also preferable to use a photo-alignment film as the alignment film.

The photo-alignment film is not particularly limited, and examples thereof include an alignment film formed by the polymer material such as a polyamide compound and a polyimide

compound described in paragraphs [0024] to [0043] of WO2005/096041A; a liquid crystal alignment film formed by the liquid crystal alignment agent having a cinnamoyl group described in JP2012-155308A; LPP-JP265CP, trade name, manufactured by Rolic Technologies Ltd.

A thickness of the alignment film is not particularly limited, but from the viewpoint of forming a liquid crystal cured layer having a uniform film thickness by relaxing the surface roughness that can be present on the support, the thickness is preferably 0.01 to 10 μm, more preferably 0.01 to 1 μm, and still more preferably 0.01 to 0.5 μm.

### Other Liquid Crystal Cured Layers

In the optical film, the liquid crystal cured layer according to the embodiment of the present invention may be formed on a surface of another liquid crystal cured layer, or another liquid crystal cured layer may be formed on a surface of the liquid crystal cured layer according to the embodiment of the present invention.

Here, examples of the other liquid crystal cured layer include a liquid crystal cured layer obtained by immobilizing the above-described liquid crystal composition according to the embodiment of the present invention in a desired alignment state. In addition, examples thereof include a liquid crystal cured layer (light absorption anisotropic film) obtained by immobilizing an alignment state of a composition containing the above-described liquid crystal compound, a polymerization initiator, the above-described dichroic substance, surfactant, solvent, and the like.

### Ultraviolet Absorber

The optical film may include an ultraviolet (UV) absorbing agent, taking an effect of external light (particularly ultraviolet rays) into consideration.

The ultraviolet absorbing agent may be contained in the liquid crystal cured layer or may also be contained in a member other than the liquid crystal cured layer, constituting the optical film. Suitable examples of the member other than the liquid crystal cured layer include a support.

As the ultraviolet absorber, any of ultraviolet absorbers known in the related art capable of exhibiting ultraviolet absorbing properties can be used. Among such the ultraviolet absorbing agents, a benzotriazole-based or hydroxyphenyltriazine-based ultraviolet absorbing agent is preferable from the viewpoint that it has high ultraviolet absorptivity and ultraviolet absorbing ability (ultraviolet-shielding ability) used for an image display apparatus is obtained.

In addition, in order to broaden ultraviolet absorbing ranges, two or more types of ultraviolet absorbing agents having different maximum absorption wavelengths are also preferably used.

Examples of an ultraviolet absorber include Tinuvin 400, Tinuvin 405, Tinuvin 460, Tinuvin 477, Tinuvin 479, Tinuvin 1577 (all manufactured by BASF), and the like. [Barrier layer (oxygen-shielding layer)]

The optical film according to the embodiment of the present invention may include a barrier layer.

Here, the barrier layer is also referred to as a gas-shielding layer (oxygen-shielding layer), and has a function of protecting from a gas such as oxygen in the air, moisture, a compound contained in an adjacent layer, or the like.

Examples of the barrier layer include a barrier layer described in paragraphs [0014] to [0054] of JP2014-159124A, paragraphs [0042] to [0075] of JP2017-121721A, paragraphs [0045] to [0054] of JP2017-115076A, paragraphs [0010] to [0061] of JP2012-213938A,

paragraphs [0021] to [0031] of JP2005-169994A, and paragraphs [0122] to [0132] of WO2020/045216A.

### Polarizing Plate

A polarizing plate according to the embodiment of the present invention has the above-mentioned optical film according to the embodiment of the present invention and a polarizer.

In a case where the liquid crystal cured layer (optically anisotropic layer) of the optical film is a positive A-plate, from the viewpoint that the optical film can be suitably applied to a circularly polarizing plate or the like, an angle formed by the slow axis of the positive A-plate and the absorption axis of a polarizer which will be described later is preferably 30° to 60°, more preferably 40° to 50°, still more preferably 42° to 48°, and particularly preferably 45°.

Here, the “slow axis” means a direction in which the in-plane refractive index of the liquid crystal cured layer is maximized, and the “absorption axis” of the polarizer means a direction in which the absorbance is the highest.

In a case where the liquid crystal cured layer (optically anisotropic layer) of the optical film is the above-mentioned optically anisotropic layer A, from the viewpoint that the optically anisotropic layer A can be suitably applied to a circularly polarizing plate or the like, the absolute value of the angle formed by the in-plane slow axis of the second region in which an alignment state of a homogeneously aligned liquid crystal compound is immobilized and the absorption axis of the polarizer is preferably 5° to 25° and more preferably 10° to 20°.

In addition, the polarizing plate can also be used as an optical compensation film for an IPS mode or FFS mode liquid crystal display device.

In a case where the polarizing plate is used as an optical compensation film for an IPS mode or FFS mode liquid crystal display device, it is preferable that the above-mentioned optically anisotropic layer is used as at least one plate of a laminate of a positive A plate or a positive C plate, an angle formed by the slow axis of the positive A plate layer and the absorption axis of a polarizer which will be described later are orthogonal or parallel, and specifically, it is more preferable that an angle formed by the slow axis of the positive A plate layer and the absorption axis of the polarizer which will be described later is 0° to 5° or 85° to 95°.

In a case where the polarizing plate according to the embodiment of the present invention is used in an image display apparatus which will be described later, it is preferable that an angle formed by the slow axis of the liquid crystal cured layer and the absorption axis of a polarizer which will be described later is parallel or orthogonal to each other.

It is noted that in the present specification, a term “parallel” does not require to be strictly parallel (an angle formed is 0°), but means that an angle formed between one and the other is less than 10°. In addition, the term “orthogonal” does not require to be strictly orthogonal (an angle formed is 90°), but means that an angle formed between one and the other is more than 80° and less than 100°.

### Polarizer

The polarizer is not particularly limited as long as it is a member functioning to convert light into specific linearly polarized light. An absorption type polarizer, a reflection type polarizer, and coating type polarizer which have been known, can be used.

Examples of the absorption type polarizer include an iodine-based polarizer, a dye-based polarizer using a dichroic dye, a polyene-based polarizer, and the like. The iodine-based polarizer and the dye-based polarizer are classified into a coating type polarizer and a stretching type polarizer. Any of these polarizers can be applied, and a polarizer produced by adsorbing iodine or a dichroic dye to polyvinyl alcohol and performing stretching is preferable.

Examples of the coating type polarizer include a polarizer including a cured product of a liquid crystal compound and a dichroic colorant.

Examples of the reflective type polarizer include a polarizer in which thin films having different birefringence are laminated, a wire grid type polarizer, a polarizer in which a cholesteric liquid crystal having a selective reflection range and a 1/4 wavelength plate are combined, and the like.

A thickness of the polarizer is not particularly limited, but is preferably 3 to 60 μm, more preferably 3 to 30 μm, and still more preferably 3 to 10 μm.

### Pressure-Sensitive Adhesive Layer

In the polarizing plate, a pressure sensitive adhesive layer may be arranged between the liquid crystal cured layer in the optical film and the polarizer.

Examples of a material forming the pressure sensitive adhesive layer used for lamination of the cured product and the polarizer include a member formed of a substance in which a ratio (tanδ=G″/G′) between a storage elastic modulus G′ and a loss elastic modulus G″, each measured with a dynamic viscoelastometer, is 0.001 to 1.5, in which a so-called pressure sensitive adhesive and a readily creepable substance are included. Examples of the pressure sensitive adhesive include polyvinyl alcohol-based pressure sensitive adhesive.

### Adhesive Layer

In the polarizing plate, an adhesive layer may be arranged between the liquid crystal cured layer in the optical film and the polarizer.

As the adhesive layer used for laminating a cured product and a polarizer, a curable adhesive composition that is cured by irradiation with active energy rays or heating is preferable.

Examples of the curable adhesive composition include a curable adhesive composition containing a cationic polymerizable compound and a curable adhesive composition containing a radical polymerizable compound.

The thickness of the adhesive layer is preferably 0.01 to 20 μm, more preferably 0.01 to 10 μm, and even more preferably 0.05 to 5 μm. In a case where the thickness of the adhesive layer is within this range, floating or peeling does not occur between the protective layer or liquid crystal cured layer and the polarizer, which are laminated. In addition, the thickness of the adhesive layer is preferably 0.4 μm or more from the viewpoint that the generation of air bubbles can be suppressed.

With regard to the adhesive layer, reference can be made to the description in paragraphs [0062] to [0080] of JP2016-035579A, the contents of which are incorporated herein by reference.

### Easy Adhesion Layer

In the polarizing plate, an easy adhesion layer may be arranged between the liquid crystal cured layer in the optical film and the polarizer. A storage elastic modulus of the easy adhesion layer at 85° C. is preferably 1.0×10⁶ to 1.0×10⁷ Pa from the viewpoints that the adhesiveness between the liquid crystal cured layer and the polarizer is excellent and the generation of cracks in the polarizer is suppressed. Examples of the constituent material of the easy adhesion layer include a polyolefin-based component and a polyvinyl alcohol-based component. A thickness of the easy adhesion layer is preferably 500 nm to 1 μm.

With regard to the easy adhesion layer, reference can be made to the description in paragraphs [0048] to [0053] of JP2018-036345A, the contents of which are incorporated herein by reference.

### Image Display Apparatus

An image display apparatus according to the embodiment of the present invention is an image display apparatus including the optical film according to the embodiment of the present invention or the polarizing plate according to the embodiment of the present invention.

The display element used in the image display apparatus is not particularly limited, examples thereof include a liquid crystal cell, an organic Electro Luminescence (hereinafter, referred to as “organic EL”) display panel, and a plasma display panel, and a liquid crystal cell or an organic EL display panel is preferable.

### Liquid Crystal Display Device

A liquid crystal display device which is an example of the image display apparatus is a liquid crystal display device having the above-mentioned polarizing plate and a liquid crystal cell.

Furthermore, it is preferable that the above-mentioned polarizing plate is used as the polarizing plate of the front side, and it is more preferable that the above-mentioned polarizing plate is used as the polarizing plates on the front and rear sides, among the polarizing plates provided on both the front and rear sides of the liquid crystal cell.

### <Liquid Crystal Cell>

The liquid crystal cell used for the liquid crystal display device is preferably in a vertical alignment (VA) mode, an optically compensated bend (OCB) mode, an in-plane-switching (IPS) mode, a fringe-field-switching (FFS) mode, or a twisted nematic (TN) mode.

### Organic EL Display Device

Examples of the organic EL display device which is an example of the image display apparatus include an aspect which includes, from the visible side, a polarizer, a λ/4 plate consisting of the above-mentioned liquid crystal cured layer, and an organic EL display panel in this order.

In addition, the organic EL display panel is a display panel constituted with an organic EL element in which an organic light emitting layer (organic electroluminescent layer) is sandwiched between electrodes (between a cathode and an anode). The configuration of the organic EL display panel is not particularly limited, and a known configuration is adopted.

### Specific Copolymer

The present invention also relates to the following specific copolymers.

A copolymer containing a repeating unit A and a repeating unit B,
in which the repeating unit A is a repeating unit represented by Formula (A1) or a repeating unit represented by Formula (A2), and
the repeating unit B is a repeating unit having at least one group selected from the group consisting of a boronic acid group, a boronic acid ester group, an epoxy group, an oxetane group, and a (meth)acryloyl group.

It is noted that the repeating unit represented by Formula (A1), the repeating unit represented by Formula (A2), and the repeating unit B except for the fact that the specific group B is limited to a part of the groups are as described above.

### EXAMPLES

Hereinafter, the present invention will be described in more detail with reference to Examples.

Materials, amounts used, ratios, treatment contents, treatment procedures, and the like provided in the following examples can be appropriately changed without departing from the gist of the present invention. Therefore, the scope of the present invention is not to be construed as limiting by Examples shown below.

### Raw Material Synthesis

### Copolymer B-1

16.0 g of cyclohexanone/isopropanol=8/2 (mass ratio) was put into a 200 mL three-neck flask equipped with a stirrer, a cooling pipe, a nitrogen introduction pipe, and a thermometer, and the inside was substituted with nitrogen gas at an internal temperature of 80° C. A solution obtained by mixing various components including 31.5 g of a monomer (SILAPLANE TM-0701T, manufactured by JNC Corporation) forming a repeating unit K-1, 4.4 g of a boronic acid monomer forming a repeating unit H-28, 2.1 g of acrylic acid (manufactured by FUJIFILM Wako Pure Chemical Corporation), 1.1 g of 1,3-propanediol (manufactured by FUJIFILM Wako Pure Chemical Corporation), 0.6 g of dimethyl 2,2′-azobis (isobutyrate) (manufactured by FUJIFILM Wako Pure Chemical Corporation), and 72.2 g of cyclohexanone/isopropanol=8/2 (mass ratio) was added dropwise thereto over 3 hours. Furthermore, a mixed solution of 0.5 g of dimethyl 2,2′-azobis (isobutyrate) and 7.3 g of cyclohexanone/isopropanol=8/2 (mass ratio) was added thereto, the mixture was stirred at an internal temperature of 80° C. for 5 hours, 4.1 g of glycidyl methacrylate (manufactured by FUJIFILM Wako Pure Chemical Corporation), 1.5 g of tetrabutylammonium bromide (manufactured by FUJIFILM Wako Pure Chemical Corporation), 0.1 g of hydroquinone monomethyl ether (manufactured by FUJIFILM Wako Pure Chemical Corporation), and 16.8 g of cyclohexanone/isopropanol=8/2 (mass ratio) were added thereto, and the mixture was reacted at an internal temperature of 85° C. for 8 hours, thereby obtaining Copolymer B-1.

Copolymer B-1 had a weight-average molecular weight of 15,300 and a molecular weight distribution of 2.7. It is noted that the above-described weight-average molecular weight and molecular weight distribution were calculated, in terms of polystyrene, by gel permeation chromatography (EcoSEC HLC-8320GPC (manufactured by Tosoh Corporation)) under measurement conditions of tetrahydrofuran as an eluent, a flow rate of 0.35 mL/min, and a temperature of 40° C., and the columns used were TSKgel SuperHZM-H, TSKgel SuperHZ4000, and TSKgel SuperHZ200 (all manufactured by Tosoh Corporation).

### Other Copolymers or Comparative Polymers

Other copolymers other than Copolymer B-1 and Comparative polymer C-1 were obtained by the same method as that for the copolymer B-1 or with reference to the method for the copolymer B-1, except that the monomer and the compositional ratio were changed to form the repeating unit of the copolymer having the structure shown in the following table.

In addition, Comparative polymer C-1 is a polyether-modified silicone (FLOW 425 manufactured by Evonik Tego chemie GmbH), and Comparative polymer C-2 is a polymer obtained by polymerizing only the monomer K-1.

Hereinafter, the structures of each copolymer or each comparative polymer will be shown.

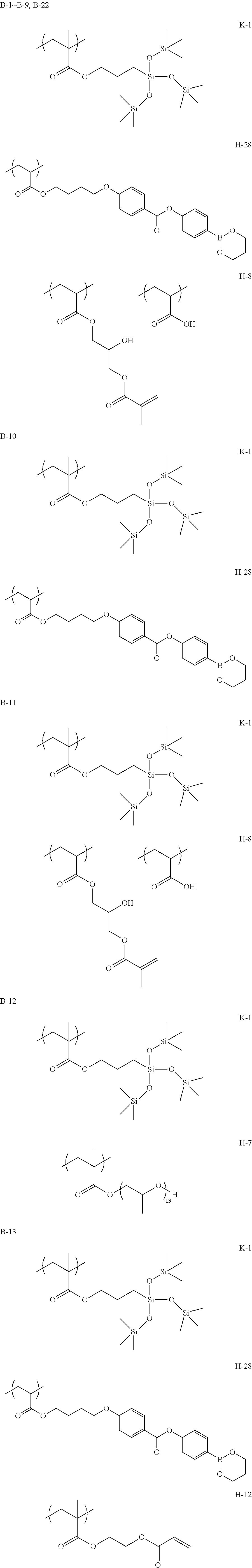

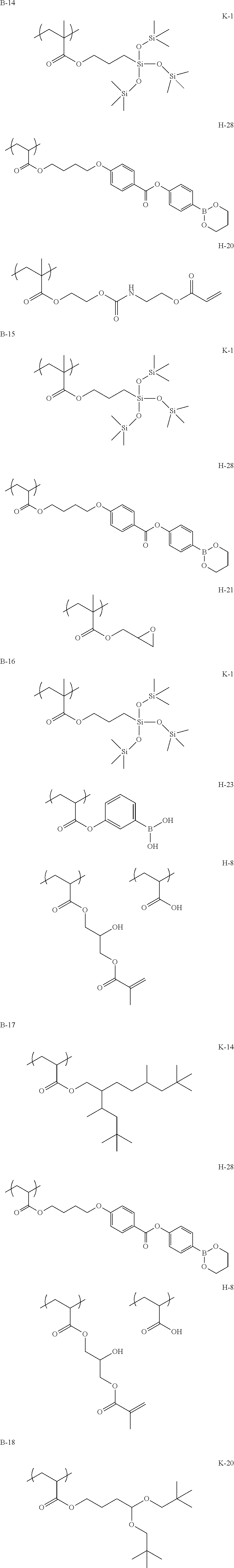

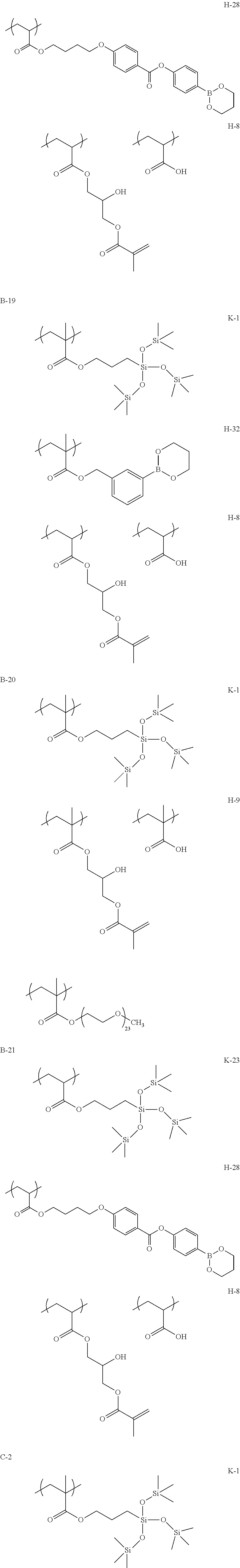

### Example 1

### Production of Optical Film

One surface of a cycloolefin polymer film (trade name: Arton film, manufactured by JSR Corporation, Re(550)=95 nm, Rth(550)=100 nm, thickness of 25 μm) was subjected to a corona treatment at a discharge amount of 125 W·min/m².

Thereafter, the liquid crystal composition (1) was applied onto the surface of the obtained cycloolefin polymer film which had been subjected to a corona treatment, using a #2.6 wire bar. The film was heated with hot air at 70° C. for 90 seconds to dry the solvent contained in the liquid crystal composition (1) and to align and mature the liquid crystal compound. Next, the film was irradiated with ultraviolet rays (irradiation amount: 300 mJ/cm²) at 40° C. and an oxygen concentration of 100 ppm by volume under nitrogen purging to immobilize the alignment of the liquid crystal compound, thereby producing an optical film having a liquid crystal cured layer. The film thickness of the liquid crystal cured layer was 0.7 μm.

TABLE 1

Composition of liquid
crystal composition (1)

| | Type | Part by mass |
|---|---|---|
| Liquid crystal | G1 | 100 |
| compound | | |
| Alignment assistant | H1 | 1 |
| Boron compound | J1 | 3 |
| Monomer | K1 | 8 |
| Polymerization | L1 | 5 |
| initiator | | |
| Copolymer | B-1 | 0.5 |

| | |
|---|---|
| Solvent | Mixed solution of aceton (87% |
| | by mass), PGMEA (10% by mass), |
| | and methanol (3% by mass |
| Concentration of | 20% by mass |
| solid contents | |

Liquid crystal compound G1: mixture of liquid crystal compounds, liquid crystal compound (RA): liquid crystal compound (RB): liquid crystal compound (RC) of 83:15:2 (mass ratio)

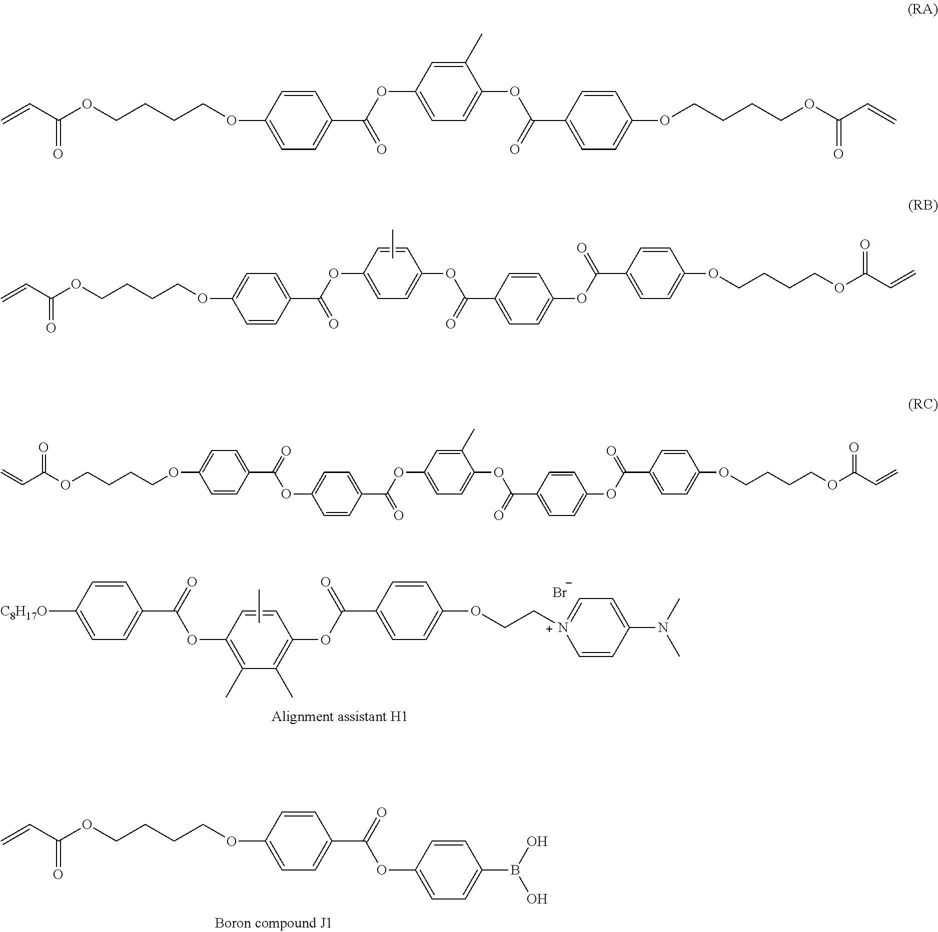

Monomer K1: VISCOAT #360 (manufactured by OSAKA ORGANIC CHEMICAL INDUSTRY LTD.)
Polymerization initiator L^{1:} OXE-01 (manufactured by BASF SE)
PGEMA: propylene glycol monomethyl ether acetate

### Production of Polarizing Plate

A cellulose acetate film (manufactured by FUJIFILM Corporation, Fujitac TD40UC) was immersed in a 1.5 mol/L sodium hydroxide aqueous solution (saponification solution) adjusted to 37° C. for 1 minute, the obtained cellulose acetate film was washed with water, immersed in a 0.05 mol/L sulfuric acid aqueous solution for 30 seconds, and passed through a water washing bath. Then, draining with an air knife was repeated 3 times. After dropping water, the film was allowed to stay in a drying zone at 70° C. for 15 seconds to be dried, and thereby a saponification-treated cellulose acetate film was produced.

Next, the obtained saponification-treated cellulose acetate film was continuously transported by guide rolls, immersed in a water bath at 30° C. to swell 1.5 times, and subjected to a stretching treatment to have a stretching ratio of 2 times. Thereafter, the film was immersed in a dyeing bath (30° C.) containing iodine and potassium iodide to perform a dyeing treatment and a stretching treatment to have a stretching ratio of 3 times. Furthermore, a crosslinking treatment and a stretching treatment were performed in an acidic bath (60° C.) to which boric acid and potassium iodide were added, thereby obtaining a stretching ratio of 6.5 times. The film was dried at 50° C. for 5 minutes to produce a polarizer having a thickness of 12 μm stretched in the longitudinal direction.

Furthermore, an adhesive layer was formed on a surface of the prepared optical film on the liquid crystal cured layer side using a 3% by mass aqueous solution of polyvinyl alcohol (manufactured by Kuraray Co., Ltd., PVA-117H) as an adhesive, and a polarizer prepared as described above was disposed on the adhesive layer. It is noted that the polarizer was disposed such that the absorption axis of the polarizer was parallel to the longitudinal direction of the optical film. Furthermore, an adhesive layer was formed on a surface of the polarizer opposite to the optical film side in the same manner as described above, the produced saponification-treated cellulose acetate film was disposed on the adhesive layer, and then lamination was performed using a roll-to-roll method to obtain a laminate. The obtained laminate was cured by drying at 70° C. for 10 minutes to produce a polarizing plate of Example 1.

It is noted that the polarizing plate of Example 1 included an optical film (cycloolefin polymer film and liquid crystal cured layer), a polarizer, and a saponification-treated cellulose acetate film in this order.

### Examples 2 to 19, 23 to 25, and Comparative Examples

In Examples 2 to 19, 23 to 25 and Comparative Examples, liquid crystal compositions were prepared by the same procedure as in Example 1, except that the copolymer B-1 of Example 1 was changed to the copolymer shown in the following table, to obtain each polarizing plate.

### Example 20

### Production of Optical Film

### <Formation of Alignment Film>

The following composition 1 for forming an alignment film was applied onto a surface of a commercially available cellulose acylate-based film (TAC film, manufactured by FUJIFILM Corporation, trade name: Fujitac TG40UL) with a wire bar. The support on which the coating film was formed was dried with hot air at 140° C. for 120 seconds to form an alignment film 1, thereby obtaining a TAC film 1 with an alignment film. A film thickness of the alignment film was 1 μm.

(Composition 1 for forming alignment film)

| | | |
|---|---|---|
| Polymer PA-1 shown below | 100.00 | parts by mass |
| Acid generator PAG-1 shown below | 8.25 | parts by mass |
| Stabilizer DIPEA shown below | 0.6 | parts by mass |
| Butyl acetate | 1001.42 | parts by mass |
| Methyl ethyl ketone | 250.36 | parts by mass |

Polymer PA-1 (in the formulae, the numerical value described in each repeating unit represents the content (% by mass) of each repeating unit with respect to all the repeating units) (weight-average molecular weight: 18,000)

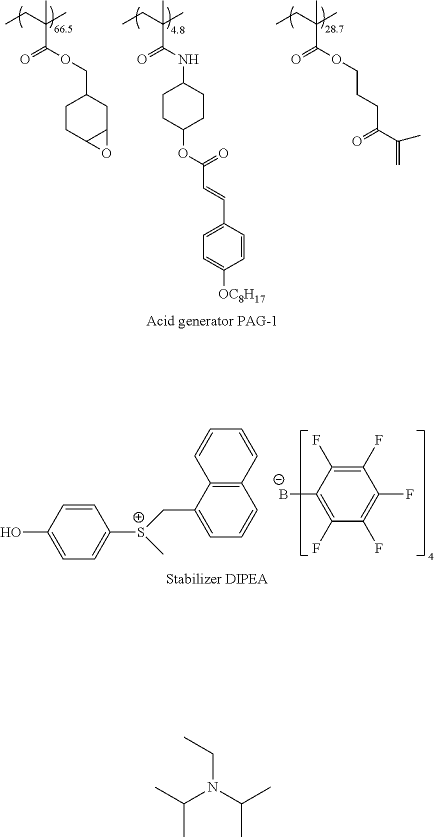

### <Formation of Light Absorption Anisotropic Layer>

The following liquid crystal composition (22) was continuously applied onto the surface of the obtained TAC film 1 with an alignment film on the alignment film side with a wire bar, heated at 120° C. for 60 seconds, and cooled to room temperature (23° C.).

Next, the coating layer was heated at 85° C. for 60 seconds, and then cooled to room temperature again.

Thereafter, the coating layer was irradiated with light from a normal direction to the film for 2 seconds under an irradiation condition of illuminance of 200 mW/cm² using a light emitting diode (LED) lamp (central wavelength of 365 nm) to form a light absorption anisotropic layer 1 on the alignment film. A film thickness of the light absorption anisotropic layer 1 was 4.5 μm.

Liquid crystal composition (22)

| | | |
|---|---|---|
| Dichroic substance D-1 shown below | 0.69 | parts by mass |
| Dichroic substance D-2 shown below | 0.17 | parts by mass |
| Dichroic substance D-3 shown below | 1.13 | parts by mass |
| Polymer liquid crystal compound P-1 | 8.67 | parts by mass |
| shown below | | |
| Liquid crystal compound G1 shown above | 1.97 | parts by mass |
| IRGACURE OXE-02 (manufactured by | 0.20 | parts by mass |
| BASF SE) | | |
| Alignment agent E-1 shown below | 0.16 | parts by mass |
| Alignment agent E-2 shown below | 0.16 | parts by mass |
| Copolymer B-1 shown above | 0.007 | parts by mass |
| Cyclopentanone | 78.17 | parts by mass |
| Benzyl alcohol | 8.69 | parts by mass |

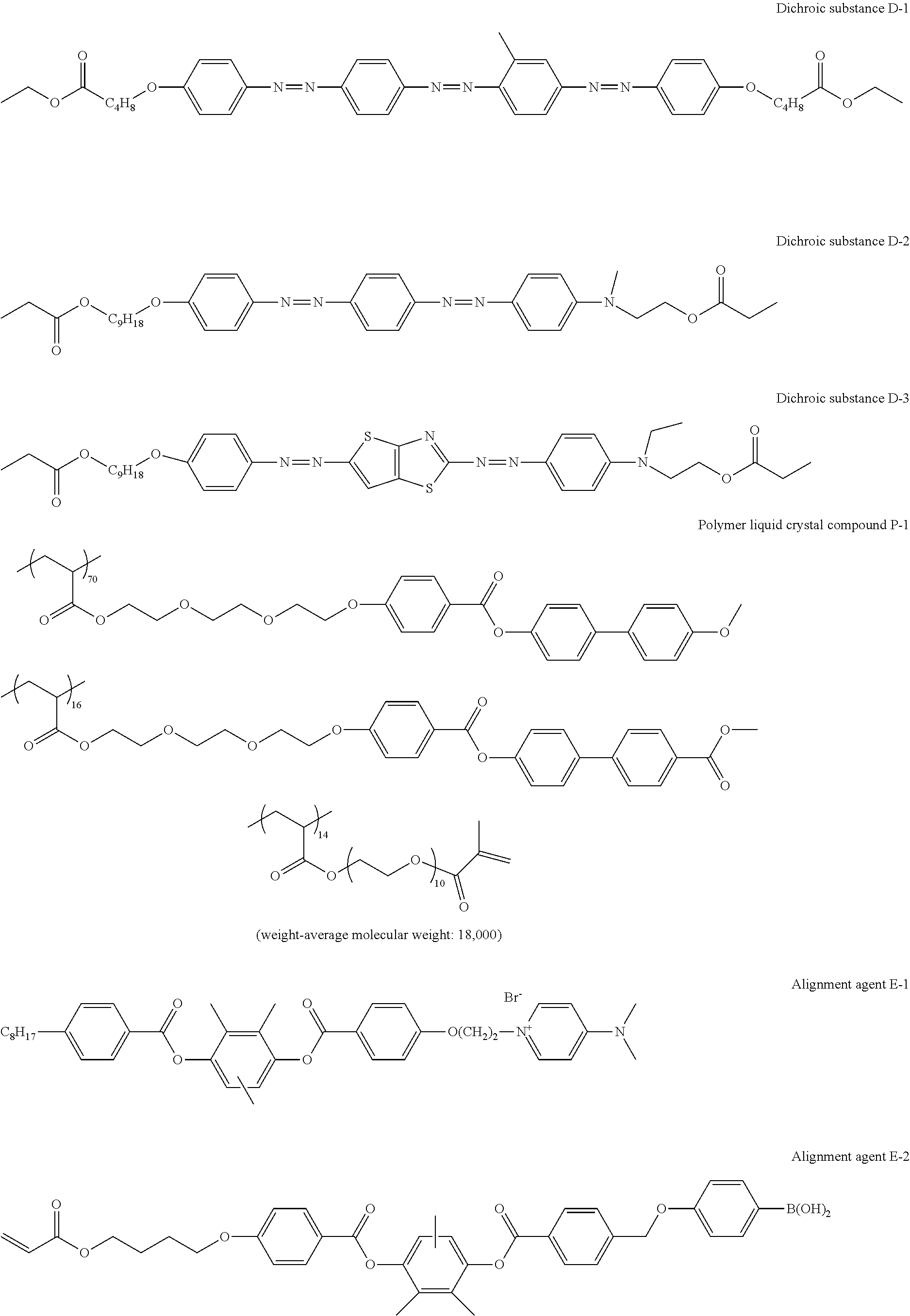

### <Formation of Barrier Layer>

The following composition 1 for forming a barrier layer was continuously applied onto the surface of the obtained light absorption anisotropic layer 1 with a wire bar to form a coating film.

Next, the support on which the coating film was formed was dried with hot air at 60° C. for 60 seconds and further dried with hot air at 100° C. for 120 seconds to form a barrier layer 1, thereby producing an optical film of Example 20. The film thickness of the barrier layer was 0.5 μm.

It is noted that the optical film of Example 20 includes a TAC film, an alignment film 1, a light absorption anisotropic layer 1, and a barrier layer 1 in this order, and as a result of measuring the transmittance central axis angle by the method described above, it was confirmed that the polar angle was 0° and the dichroic substance contained in the light absorption anisotropic layer was vertically aligned.

(Composition 1 for forming barrier layer)

| | | |
|---|---|---|
| Modified polyvinyl alcohol | 3.88 | parts by mass |
| PVA-1 shown below | | |
| IRGACURE 2959 | 0.20 | parts by mass |
| Water | 70 | parts by mass |
| Methanol | 30 | parts by mass |

Modified polyvinyl alcohol PVA-1 (weight-average molecular weight: 14,000)

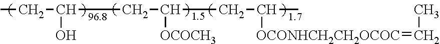

### Production of Polarizing Plate

A polarizer and a polarizing plate were produced by the same procedure as in Example 1 using the obtained optical film of Example 20.

It is noted that the obtained polarizing plate includes an optical film (TAC film, alignment film 1, light absorption anisotropic layer 1, and barrier layer 1), a polarizer, and a saponification-treated cellulose acetate film in this order.

### Example 21

An optical film of Example 21 was produced by the same procedure as in Example 20, except that the composition 1 for forming a barrier layer was changed to the following composition 2 for forming a barrier layer in Example 20, thereby obtaining a polarizing plate. The transmittance central axis angle of the optical film of Example 21 was a polar angle of 0°.

(Composition 2 for forming barrier layer)

| | | |
|---|---|---|
| Modified polyvinyl alcohol | 3.88 | parts by mass |
| PVA-1 shown above | | |
| IRGACURE 2959 | 0.20 | parts by mass |
| Surfactant S-1 shown below | 0.0018 | parts by mass |
| Water | 70 | parts by mass |
| Methanol | 30 | parts by mass |

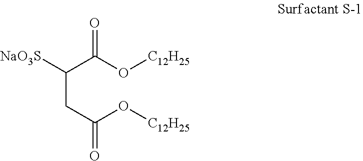

### Example 22

An optical film of Example 22 was produced by the same procedure as in Example 20, except that the liquid crystal composition (22) was changed to the following liquid crystal composition (23) in Example 20, thereby obtaining a polarizing plate. The transmittance central axis angle of the optical film of Example 22 was a polar angle of 0°.

Liquid crystal composition (23)

| | | |
|---|---|---|
| Dichroic substance D-4 shown below | 2.8 | parts by mass |
| Dichroic substance D-5 shown below | 2.8 | parts by mass |
| Dichroic substance D-6 shown below | 2.8 | parts by mass |
| Liquid crystal compound G-2 shown below | 75 | parts by mass |
| Liquid crystal compound G-3 shown below | 25 | parts by mass |
| IRGACURE 369 (manufactured by BASF SE) | 6 | parts by mass |
| Copolymer B-1 shown above | 0.3 | parts by mass |
| o-xylene | 250 | parts by mass |

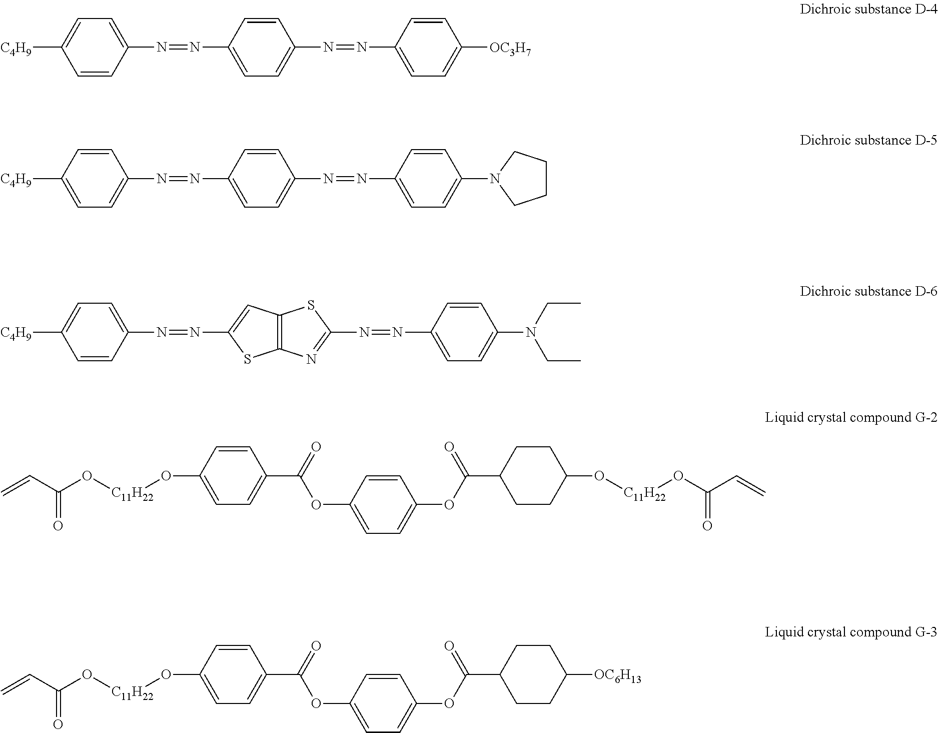

### Evaluation

### Evaluation of Leveling Properties

The static surface tension of each of the liquid crystal compositions shown in the following table was measured twice with a static surface tension meter (model number: CBVP-Z) manufactured by Kyowa Interface Science Co., Ltd., and the average value thereof was evaluated according to the following evaluation standard. The lower the value of the static surface tension, the better the leveling properties, and an evaluation of B or higher is preferable.
“A”: less than 26.0 mN/m “B”: 26.0 mN/m or more and less than 26.5 mN/m
“C”: 26.5 mN/m or more and less than 27.5 mN/m
“D”: 27.5 mN/m or greater and less than 28.5 mN/m
“E”: 28.5 mN/m or more

### Evaluation of Compatibility

The compatibility was evaluated using the composition for evaluating compatibility.

In the above-described liquid crystal composition (1), only the amount of the solvent used was adjusted to obtain a composition (1) for evaluating compatibility, having a concentration of solid contents of 45% by mass. Compositions (2) to (27) for evaluating compatibility corresponding to the liquid crystal compositions (2) to (27) were prepared by the same procedure as described above, and the compatibility was evaluated.

For each composition for evaluating compatibility, absorbance was measured using an ultraviolet-visible-near infrared spectrophotometer (model number: UV-2600) manufactured by Shimadzu Corporation, under the following conditions: cell length: 10 mm, measurement wavelength range: 500 to 700 nm, scan speed: high speed, sampling pitch: 1 nm, and slit width: 1 mm, and the absorbance at a wavelength of 660 nm was evaluated according to the following evaluation standard. It is noted that the above-described absorbance value is a value used as a reference using a reference composition containing the same amount of the same component as the composition for evaluating compatibility, except that the composition for evaluating compatibility does not contain a copolymer. It is noted that the lower the absorbance value, the better the compatibility, and an evaluation of C or higher is preferable.
“A”: less than 0.03
“B”: 0.03 or more and less than 0.06
“C”: 0.06 or more and less than 0.15
“D”: 0.15 or more and less than 0.30
“E”: 0.30 or more

### Adhesiveness

The adhesiveness was evaluated by a cross-cut method described in JIS-K-5600-5-6-1.

In each of the prepared polarizing plates, 100 grids were formed on the surface of the optical film at an interval of 1 mm, and an adhesion test was performed using cellophane tape (manufactured by NICHIBAN Co., Ltd.). The cellophane tape was peeled off, and the evaluation was performed based on the following evaluation standards. It is noted that, in Examples 1 to 19 and 23 to 25, the grid was produced by making cuts from the cycloolefin polymer film (support) side of the optical film down to the surface of the polarizer, and in Examples 20 to 22, the grid was produced by making cuts from the TAC film (support) side of the optical film down to the surface of the barrier layer 1. In a case where the evaluation result is any of the evaluation A, the evaluation B, or the evaluation C, there is no problem in practical use, and the evaluation A is preferable.
“A”: The number of squares in the grid without peeling was 100.
“B”: The number of squares in the grid without peeling was 60 to 99.
“C”: The number of squares in the grid without peeling was 40 to 59.
“D”: The number of squares in the grid without peeling was 20 to 39.
“E”: The number of squares in the grid without peeling was 19 or less.

In the following table, the evaluation results are shown.

The column of “Formula (A1), Formula (A2)” of “Repeating unit A” indicates that in a case of “Formula (A1)”, the repeating unit A of the copolymer or comparative polymer corresponds to a repeating unit represented by Formula (A1), and in a case of “Formula (A2)”, the repeating unit A of the copolymer or comparative polymer corresponds to a repeating unit represented by Formula (A2).

The column of “Substituent” of “Repeating unit A” indicates that in a case of “SI”, the repeating unit A has a substituent SI, in a case of “LQ”, the repeating unit A has a substituent LQ, and in a case of “LR” the repeating unit A has a substituent LR.

The column of “Specific group B” in “Repeating unit B” indicates the type of the specific group B.

The column of “Type” of “Repeating unit C” indicates the type of the repeating unit C, and “AA” indicates a repeating unit derived from acrylic acid (manufactured by FUJIFILM Wako Pure Chemical Corporation).

The column of “Type” of “Repeating unit D” indicates the type of the repeating unit D, and “PEGMA” indicates a repeating unit derived from methoxypolyethylene glycol methacrylate (manufactured by Shin-Nakamura Chemical Co., Ltd.).

“Mw” indicates the weight-average molecular weight of the copolymer or the comparative polymer. The method of measuring the weight-average molecular weight is as described above.

“mol %” of various repeating units indicates the content (mol %) of the various repeating units with respect to all the repeating units of the copolymer or comparative polymer.

TABLE 2

| | | Copolymer or comparative polymer | | | | | | | | | |
|---|---|---|---|---|---|---|---|---|---|---|---|
| | Liquid | | Repeating unit A | | | | Repeating unit B | | | | |
| | crystal | | | | Formula | | B1 | | | | |
| | compo- | | | | (A1) or | | | | Specific | B2 | |
| | sition | No. | Type | mol % | (A2) | Substitutent | Type | mol % | group B | Type | mol % |
| Example 1 | 1 | B-1 | K-1 | 65 | Formula | SI | H-28 | 10 | Boronic acid | H-8 | 24 |
| | | | | | (A1) | | | | ester group | | |
| Example 2 | 2 | B-2 | K-1 | 65 | Formula | SI | H-28 | 10 | Boronic acid | H-8 | 24 |
| | | | | | (A1) | | | | ester group | | |
| Example 3 | 3 | B-3 | K-1 | 65 | Formula | SI | H-28 | 10 | Boronic acid | H-8 | 24 |
| | | | | | (A1) | | | | ester group | | |
| Example 4 | 4 | B-4 | K-1 | 65 | Formula | SI | H-28 | 10 | Boronic acid | H-8 | 24 |
| | | | | | (A1) | | | | ester group | | |
| Example 5 | 5 | B-5 | K-1 | 65 | Formula | SI | H-28 | 10 | Boronic acid | H-8 | 24 |
| | | | | | (A1) | | | | ester group | | |
| Example 6 | 6 | B-6 | K-1 | 70 | Formula | SI | H-28 | 8 | Boronic acid | H-8 | 21 |
| | | | | | (A1) | | | | ester group | | |
| Example 7 | 7 | B-7 | K-1 | 75 | Formula | SI | H-28 | 5 | Boronic acid | H-8 | 19 |
| | | | | | (A1) | | | | ester group | | |
| Example 8 | 8 | B-8 | K-1 | 40 | Formula | SI | H-28 | 20 | Boronic acid | H-8 | 38 |
| | | | | | (A1) | | | | ester group | | |
| Example 9 | 9 | B-9 | K-1 | 35 | Formula | SI | H-28 | 25 | Boronic acid | H-8 | 38 |
| | | | | | (A1) | | | | ester group | | |
| Example 10 | 10 | B-10 | K-1 | 65 | Formula | SI | H-28 | 35 | Boronic acid | — | — |
| | | | | | (A1) | | | | ester group | | |
| Example 11 | 11 | B-11 | K-1 | 65 | Formula | SI | H-8 | 33 | Methacryloyl | — | — |
| | | | | | (A1) | | | | group | | |
| Example 12 | 12 | B-12 | K-1 | 65 | Formula | SI | H-3 | 35 | Hydroxy group | — | — |
| | | | | | (A1) | | | | | | |
| Example 13 | 13 | B-13 | K-1 | 65 | Formula | SI | H-28 | 10 | Boronic acid | H-12 | 25 |
| | | | | | (A1) | | | | ester group | | |
| Example 14 | 14 | B-14 | K-1 | 65 | Formula | SI | H-28 | 10 | Boronic acid | H-20 | 25 |
| | | | | | (A1) | | | | ester group | | |
| Example 15 | 15 | B-15 | K-1 | 65 | Formula | SI | H-28 | 10 | Boronic acid | H-21 | 25 |
| | | | | | (A1) | | | | ester group | | |
| Example 16 | 16 | B-16 | K-1 | 65 | Formula | SI | H-28 | 10 | Boronic acid | H-8 | 24 |
| | | | | | (A1) | | | | group | | |
| Example 17 | 17 | B-17 | K-14 | 65 | Formula | LQ | H-28 | 10 | Boronic acid | H-8 | 24 |
| | | | | | (A1) | | | | ester group | | |
| Example 18 | 18 | B-18 | K-20 | 65 | Formula | LR | H-28 | 10 | Boronic acid | H-8 | 24 |
| | | | | | (A2) | | | | ester group | | |
| Example 19 | 21 | B-19 | K-1 | 65 | Formula | SI | H-32 | 10 | Boronic acid | H-8 | 24 |
| | | | | | (A1) | | | | ester group | | |
| Example 20 | 22 | B-1 | K-1 | 65 | Formula | SI | H-28 | 10 | Boronic acid | H-8 | 24 |
| | | | | | (A1) | | | | ester group | | |
| Example 21 | 23 | B-1 | K-1 | 65 | Formula | SI | H-28 | 10 | Boronic acid | H-8 | 24 |
| | | | | | (A1) | | | | ester group | | |
| Example 22 | 24 | B-1 | K-1 | 65 | Formula | SI | H-28 | 10 | Boronic acid | H-8 | 24 |
| | | | | | (A1) | | | | ester group | | |
| Example 23 | 25 | B-20 | K-1 | 65 | Formula | SI | H-9 | 24 | Methacryloyl | — | — |
| | | | | | (A1) | | | | group | | |
| Example 24 | 26 | B-21 | K-23 | 65 | Formula | SI | H-28 | 10 | Boronic acid | H-8 | 24 |
| | | | | | (A1) | | | | ester group | | |
| Example 25 | 27 | B-22 | K-1 | 85 | Formula | SI | H-28 | 3 | Boronic acid | H-8 | 11 |
| | | | | | (A1) | | | | ester group | | |
| Comparative | 19 | C-1 | Polyether-modified silicone | | | | | | | | |
| Example 1 | | | | | | | | | | | |
| Comparative | 20 | C-2 | K-1 | 100 | Formula | SI | — | — | — | — | — |
| Example 2 | | | | | (A1) | | | | | | |

| | Copolymer or comparative polymer | | | | | | | | |
|---|---|---|---|---|---|---|---|---|---|
| | Repeating unit B | | | | | | | | |
| | B2 | Repeating | | Repeating | | | Evaluation | | |
| | Specific | unit C | | unit D | | | Leveling | Compat- | Adhe- |
| | group B | Type | mol % | Type | mol % | Mw | properties | ibility | siveness |
| Example 1 | Methacryloyl | AA | 1 | — | — | 15,300 | A | A | A |
| | group | | | | | | | | |
| Example 2 | Methacryloyl | AA | 1 | — | — | 78,000 | A | A | A |
| | group | | | | | | | | |
| Example 3 | Methacryloyl | AA | 1 | — | — | 85,000 | A | B | A |
| | group | | | | | | | | |
| Example 4 | Methacryloyl | AA | 1 | — | — | 11,000 | A | A | A |
| | group | | | | | | | | |
| Example 5 | Methacryloyl | AA | 1 | — | — | 7,500 | B | A | A |
| | group | | | | | | | | |
| Example 6 | Methacryloyl | AA | 1 | — | — | 15,800 | A | A | A |
| | group | | | | | | | | |
| Example 7 | Methacryloyl | AA | 1 | — | — | 16,400 | A | B | A |
| | group | | | | | | | | |
| Example 8 | Methacryloyl | AA | 2 | — | — | 16,200 | A | A | A |
| | group | | | | | | | | |
| Example 9 | Methacryloyl | AA | 2 | — | — | 15,900 | B | A | A |
| | group | | | | | | | | |
| Example 10 | — | — | — | — | — | 12,000 | A | A | B |
| Example 11 | — | AA | 2 | — | — | 12,400 | A | A | B |
| Example 12 | — | — | — | — | — | 16,000 | A | A | C |
| Example 13 | Acryloyl | — | — | — | — | 14,600 | A | A | A |
| | group | | | | | | | | |
| Example 14 | Acryloyl | — | — | — | — | 13,700 | A | A | A |
| | group | | | | | | | | |
| Example 15 | Epoxy group | — | — | — | — | 14,800 | A | A | B |
| Example 16 | Methacryloyl | AA | 1 | — | — | 16,300 | A | A | A |
| | group | | | | | | | | |
| Example 17 | Methacryloyl | AA | 1 | — | — | 17,100 | B | A | A |
| | group | | | | | | | | |
| Example 18 | Methacryloyl | AA | 1 | — | — | 17,500 | B | A | A |
| | group | | | | | | | | |
| Example 19 | Methacryloyl | AA | 1 | — | — | 16,300 | A | A | A |
| | group | | | | | | | | |
| Example 20 | Methacryloyl | AA | 1 | — | — | 15,300 | A | A | A |
| | group | | | | | | | | |
| Example 21 | Methacryloyl | AA | 1 | — | — | 15,300 | A | A | A |
| | group | | | | | | | | |
| Example 22 | Methacryloyl | AA | 1 | — | — | 15,300 | A | A | A |
| | group | | | | | | | | |
| Example 23 | — | AA | 2 | PEGMA | 9 | 15,800 | A | A | A |
| Example 24 | Methacryloyl | AA | 1 | — | — | 16,300 | A | A | A |
| | group | | | | | | | | |
| Example 25 | Methacryloyl | AA | 1 | — | — | 17,300 | A | C | A |
| | group | | | | | | | | |
| Comparative | Polyether-modified silicone | | | — | — | — | C | D | C |
| Example 1 | | | | | | | | | |
| Comparative | — | — | — | — | — | 15,200 | A | D | B |
| Example 2 | | | | | | | | | |

From the results shown in Table 1, it was found that in a case where the liquid crystal composition did not contain the specific copolymer, at least one of leveling properties, compatibility, or adhesiveness was deteriorated (Comparative Examples 1 and 2).

On the other hand, it was found that in a case where the liquid crystal composition contains the specific copolymer, the leveling properties, the compatibility, and the adhesiveness are excellent (Examples 1 to 22).

It was found that in a case where the weight-average molecular weight of the specific copolymer is 8,000 or more and less than 80,000, the leveling properties or the compatibility is more excellent (Examples 1 to 5).

It was found that in a case where the content of the repeating unit A was 40 to 70 mol % with respect to all repeating units of the specific copolymer, the leveling properties or the compatibility was more excellent (Examples 6 to 9).

In addition, it was found that in a case where the content of the repeating unit A was 30 to 80 mol % with respect to all repeating units of the specific copolymer, the compatibility was more excellent (Examples 1 and 6 to 9).

It was found that in a case where the repeating unit B contained at least two groups selected from the group consisting of a hydroxy group, a boronic acid group, a boronic acid ester group, an epoxy group, an oxetane group, a vinyl group, and a (meth)acryloyl group, the adhesiveness was more excellent (Examples 1, 10 to 12).

It was found that in a case where the repeating unit B was a group having at least one group selected from the group consisting of a boronic acid group, a boronic acid ester group, a vinyl group, and a (meth)acryloyl group, the adhesiveness was more excellent (Examples 1, 10 to 12, and 15).

It was found that in a case where the repeating unit A was a repeating unit represented by Formula (a1) (the repeating unit A was a repeating unit represented by Formula (A1), and Rh in Formula (A1) was a substituent SI), the leveling properties were more excellent (Examples 1, 17, and 18).

### EXPLANATION OF REFERENCES

10: optical film
12: liquid crystal cured layer
14: alignment film
16: support

What is claimed is:

1. A liquid crystal composition comprising:
a copolymer containing a repeating unit A and a repeating unit B; and
a liquid crystal compound,
wherein the repeating unit A is a repeating unit represented by Formula (A1) or a repeating unit represented by Formula (A2),
the repeating unit B is a repeating unit having at least one group selected from the group consisting of a hydroxy group, a boronic acid group, a boronic acid ester group, a boronic acid amide group, an epoxy group, an oxetane group, a vinyl group, a styryl group, a (meth)acryloyl group, and a maleimide group, and
a content of the repeating unit A is 30 to 80 mol % with respect to all repeating units of the copolymer, 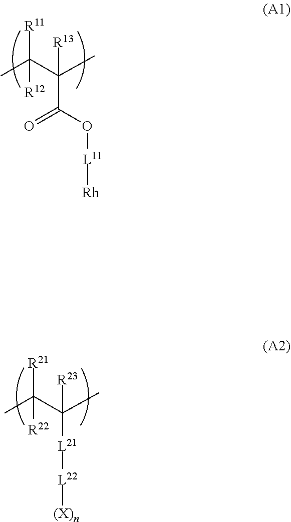
in Formula (A1),
R¹¹ and R¹² each independently represent a hydrogen atom or an alkyl group,
R¹³ represents a hydrogen atom or a substituent,
L¹¹ represents a single bond or a divalent linking group, and
Rh represents a substituent having two or more groups represented by Formula (S) and not having a fluorine atom, or a hydrocarbon group having 10 or more carbon atoms, which has two or more terminal methyl groups, in Formula (A2),
R²¹ and R²² each independently represent a hydrogen atom or an alkyl group,
R²³ represents a hydrogen atom or a substituent,
L²¹ represents a single bond or a divalent linking group,
L²² represents an (n+1)-valent linking group having a heteroatom,
X represents an alkyl group having 5 to 40 carbon atoms, which has two or more terminal methyl groups, and
n represents an integer of 2 or more,
provided that a plurality of X's may be the same as or different from each other, 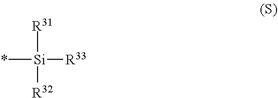
in Formula (S),
* represents a bonding position, and R³¹, R³², and R³³ each independently represent an alkyl group, an alkenyl group, an aryl
group, or an alkylenearyl group,
provided that in the substituent having two or more groups represented by Formula (S) and not having a fluorine atom, a plurality of R³¹'s may be the same as or different from each other, a plurality of R³²'s may be the same as or different from each other, and a plurality of R³³'s may be the same as or different from each other.

2. The liquid crystal composition according to claim 1,
wherein the repeating unit B is a repeating unit represented by Formula (B1), 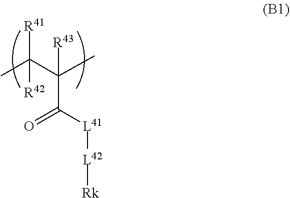
in Formula (B1),
R⁴¹ and R⁴² each independently represent a hydrogen atom or an alkyl group,
R⁴³ represents a hydrogen atom or a substituent,
L⁴¹ represents —O— or —NR^{Z}-, and R^{Z} represents a hydrogen atom or a substituent,
L⁴² represents a single bond or a divalent linking group, and
Rk represents a group having at least one group selected from the group consisting of a boronic acid group, a boronic acid ester group, an epoxy group, an oxetane group, a vinyl group, and a (meth)acryloyl group.

3. The liquid crystal composition according to claim 1,
wherein the repeating unit A is a repeating unit represented by Formula (a1), 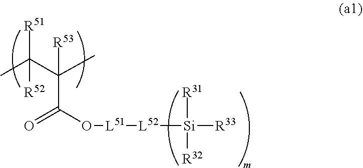
in Formula (a1),
R⁵¹ and R⁵² each independently represent a hydrogen atom or an alkyl group,
R⁵³ represents a hydrogen atom or a substituent,
L⁵¹ represents a single bond or an alkylene group having 1 to 6 carbon atoms,
L⁵² represents an (m+1)-valent linking group not having a fluorine atom,
R³¹, R³², and R³³ each independently represent an alkyl group, an alkenyl group, an aryl group, or an alkylenearyl group, provided that a plurality of R³¹'s may be the same as or different from each other, a plurality of R³²'s may be the same as or different from each other, and a plurality of R³³'s may be the same as or different from each other, and
m represents an integer of 2 or more.

4. The liquid crystal composition according to claim 1,
wherein a weight-average molecular weight of the copolymer is 8,000 or more and less than 80,000.

5. The liquid crystal composition according to claim 1,
wherein the repeating unit B has at least two groups selected from the group consisting of a hydroxy group, a boronic acid group, a boronic acid ester group, an epoxy group, an oxetane group, a vinyl group, and a (meth)acryloyl group.

6. The liquid crystal composition according to claim 1,
wherein a content of the repeating unit A is 40 to 70 mol % with respect to all repeating units of the copolymer.

7. The liquid crystal composition according to claim 1,
wherein the liquid crystal compound is a polymerizable liquid crystal compound.

8. The liquid crystal composition according to claim 7,
wherein the polymerizable liquid crystal compound is at least one polymerizable liquid crystal compound selected from the group consisting of a polymerizable rod-like liquid crystal compound and a polymerizable disk-like liquid crystal compound.

9. The liquid crystal composition according to claim 1, further comprising:
a dichroic substance.

10. A liquid crystal cured layer obtained by immobilizing an alignment state of the liquid crystal compound in the liquid crystal composition according to claim 1.

11. An optical film comprising:
the liquid crystal cured layer according to claim 10.

12. A polarizing plate comprising:
the optical film according to claim 11; and
a polarizer.

13. An image display apparatus comprising:
the optical film according to claim 11.

14. A liquid crystal composition comprising:
a copolymer containing a repeating unit A and a repeating unit B; and
a liquid crystal compound,
wherein the repeating unit A is a repeating unit represented by Formula (A1) or a repeating unit represented by Formula (A2),
the repeating unit B is a repeating unit having at least one group selected from the group consisting of a hydroxy group, a boronic acid group, a boronic acid ester group, a boronic acid amide group, an epoxy group, an oxetane group, a vinyl group, a styryl group, a (meth)acryloyl group, and a maleimide group,
the copolymer may further contain another repeating unit,
the another repeating unit is a repeating unit derived from at least one compound selected from the group consisting of (meth)acrylic acid, an acrylic acid ester compound, a methacrylic acid ester compound, a maleimide compound, an acrylamide compound, acrylonitrile, a maleic acid anhydride, a styrene compound, and a vinyl compound, and
the total content of the repeating unit A, the repeating unit B, and the another repeating unit is 99 to 100 mol % with respect to all repeating units of the copolymer, 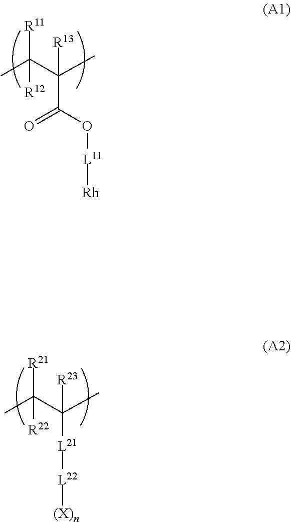
in Formula (A1),
R¹¹ and R¹² each independently represent a hydrogen atom or an alkyl group,
R¹³ represents a hydrogen atom or a substituent,
L¹¹ represents a single bond or a divalent linking group, and
Rh represents a substituent having two or more groups represented by Formula (S) and not having a fluorine atom, or a hydrocarbon group having 10 or more carbon atoms, which has two or more terminal methyl groups,
in Formula (A2),
R²¹ and R²² each independently represent a hydrogen atom or an alkyl group,
R²³ represents a hydrogen atom or a substituent,
L²¹ represents a single bond or a divalent linking group,
L²² represents an (n+1)-valent linking group having a heteroatom,
X represents an alkyl group having 5 to 40 carbon atoms, which has two or more terminal methyl groups, and
n represents an integer of 2 or more,
provided that a plurality of X's may be the same as or different from each other, 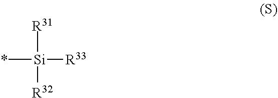
in Formula (S),
* represents a bonding position, and
R³¹, R³², and R³³ each independently represent an alkyl group, an alkenyl group, an aryl group, or an alkylenearyl group,
provided that in the substituent having two or more groups represented by Formula (S) and not having a fluorine atom, a plurality of R³¹'s may be the same as or different from each other, a plurality of R³²'s may be the same as or different from each other, and a plurality of R³³'s may be the same as or different from each other.

15. A copolymer comprising:
a repeating unit A; and
a repeating unit B,
wherein the repeating unit A is a repeating unit represented by Formula (A1) or a repeating unit represented by Formula (A2),
the repeating unit B is a repeating unit having at least one group selected from the group consisting of a boronic acid group, a boronic acid ester group, an epoxy group, an oxetane group, and a (meth)acryloyl group, and
a content of the repeating unit A is 30 to 80 mol % with respect to all repeating units of the copolymer, 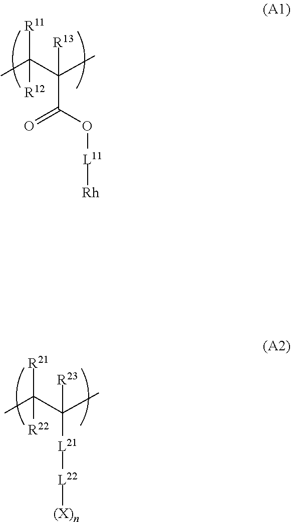
in Formula (A1),
R¹¹ and R¹² each independently represent a hydrogen atom or an alkyl group,
R¹³ represents a hydrogen atom or a substituent,
L¹¹ represents a single bond or a divalent linking group, and
Rh represents a substituent having two or more groups represented by Formula (S) and not having a fluorine atom, or a hydrocarbon group having 10 or more carbon atoms, which has two or more terminal methyl groups,
in Formula (A2),
R²¹ and R²² each independently represent a hydrogen atom or an alkyl group,
R²³ represents a hydrogen atom or a substituent,
L²¹ represents a single bond or a divalent linking group,
L²² represents an (n+1)-valent linking group having a heteroatom,
X represents an alkyl group having 5 to 40 carbon atoms, which has two or more terminal methyl groups, and
n represents an integer of 2 or more,
provided that a plurality of X's may be the same as or different from each other, 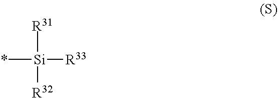
in Formula (S),
* represents a bonding position, and
R³¹, R³², and R³³ each independently represent an alkyl group, an alkenyl group, an aryl group, or an alkylenearyl group,
provided that in the substituent having two or more groups represented by Formula (S) and not having a fluorine atom, a plurality of R³¹'s may be the same as or different from each other, a plurality of R³²'s may be the same as or different from each other, and a plurality of R³³'s may be the same as or different from each other.

16. A copolymer comprising:
a repeating unit A; and
a repeating unit B,
wherein the repeating unit A is a repeating unit represented by Formula (A1) or a repeating unit represented by Formula (A2),
the repeating unit B is a repeating unit having at least one group selected from the group consisting of a boronic acid group, a boronic acid ester group, an epoxy group, an oxetane group, and a (meth)acryloyl group,
the copolymer may further contain another repeating unit,
the another repeating unit is a repeating unit derived from at least one compound selected from the group consisting of (meth)acrylic acid, an acrylic acid ester compound, a methacrylic acid ester compound, a maleimide compound, an acrylamide compound, acrylonitrile, a maleic acid anhydride, a styrene compound, and a vinyl compound, and
the total content of the repeating unit A, the repeating unit B, and the another repeating unit is 99 to 100 mol % with respect to all repeating units of the copolymer, 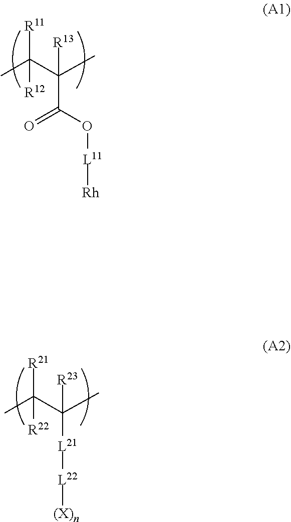
in Formula (A1),
R¹¹ and R¹² each independently represent a hydrogen atom or an alkyl group,
R¹³ represents a hydrogen atom or a substituent,
L¹¹ represents a single bond or a divalent linking group, and
Rh represents a substituent having two or more groups represented by Formula (S) and not having a fluorine atom, or a hydrocarbon group having 10 or more carbon atoms, which has two or more terminal methyl groups,
in Formula (A2),
R²¹ and R²² each independently represent a hydrogen atom or an alkyl group,
R²³ represents a hydrogen atom or a substituent,
L²¹ represents a single bond or a divalent linking group,
L²² represents an (n+1)-valent linking group having a heteroatom,
X represents an alkyl group having 5 to 40 carbon atoms, which has two or more terminal methyl groups, and
n represents an integer of 2 or more,
provided that a plurality of X's may be the same as or different from each other, 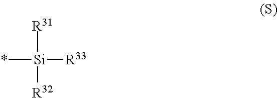
in Formula (S),
* represents a bonding position, and
R³¹, R³², and R³³ each independently represent an alkyl group, an alkenyl group, an aryl group, or an alkylenearyl group,
provided that in the substituent having two or more groups represented by Formula (S) and not having a fluorine atom, a plurality of R³¹'s may be the same as or different from each other, a plurality of R³²'s may be the same as or different from each other, and a plurality of R³³'s may be the same as or different from each other.
